(19) United States
(12) Patent Application Publication
(10) Pub. No.: US 2025/0093429 A1
(43) Pub. Date: Mar. 20, 2025

(54) DETECTION DEVICE, DETECTION SYSTEM, TRANSMISSION LINE, AND DETECTION METHOD

(71) Applicants: Sumitomo Electric Industries, Ltd., Osaka-shi, Osaka (JP); Sumitomo Wiring Systems, Ltd., Yokkaichi-shi, Mie (JP); AutoNetworks Technologies, Ltd., Yokkaichi-shi, Mie (JP)

(72) Inventors: Masato IZAWA, Osaka-shi, Osaka (JP); Isao KATO, Osaka-shi, Osaka (JP); Hirokazu KOMORI, Osaka-shi, Osaka (JP); Fujio SONODA, Osaka-shi, Osaka (JP)

(73) Assignees: Sumitomo Electric Industries, Ltd., Osaka-shi, Osaka (JP); Sumitomo Wiring Systems, Ltd., Yokkaichi-shi, Mie (JP); AutoNetworks Technologies, Ltd., Yokkaichi-shi, Mie (JP)

(21) Appl. No.: 18/832,518

(22) PCT Filed: Dec. 26, 2022
(86) PCT No.: PCT/JP2022/047804

§ 371 Date: Jul. 24, 2024

(30) Foreign Application Priority Data
Jan. 28, 2022 (JP) 2022-011596

(51) Int. Cl. G01R 31/58

(52) U.S. Cl. CPC G01R 31/58

(57) ABSTRACT

A detection device includes: a signal output unit configured to output a measurement signal having a frequency component to a transmission line; a measurement unit configured to receive, from the transmission line, a response signal including a signal in which the measurement signal is reflected, and measure at least one of an amplitude and a phase of the received response signal; and a detection unit configured to calculate an evaluation value based on a measurement result obtained by the measurement unit, and detect a partial damage of the transmission line, based on the calculated evaluation value.

### TECHNICAL FIELD

The present disclosure relates to a detection device, a detection system, a transmission line, and a detection method.

This application claims priority on Japanese Patent Application No. 2022-11596 filed on Jan. 28, 2022, the entire content of which is incorporated herein by reference.

### BACKGROUND ART

PATENT LITERATURE 1 (Japanese Laid-Open Patent Publication No. 2007-305478) discloses an electric cable breakage detection device as follows. That is, the electric cable breakage detection device includes: an electric cable composed of a plurality of electric wires, an electrical shield layer covering the plurality of electric wires, and a sheath covering the electrical shield layer; a breakage detection wire that is provided on the electrical shield layer and includes a conductor wire and an insulating layer on the outer periphery of the conductor wire; a voltage source electrically connected to the conductor wire; a first detector electrically connected to the conductor wire; and a second detector electrically connected to the electrical shield layer.

### CITATION LIST

### Patent Literature

PATENT LITERATURE 1: Japanese Laid-Open Patent Publication No. 2007-305478

### SUMMARY OF THE INVENTION

A detection device according to the present disclosure includes: a signal output unit configured to output a measurement signal having a frequency component to a transmission line; a measurement unit configured to receive, from the transmission line, a response signal including a signal in which the measurement signal is reflected, and measure at least one of an amplitude and a phase of the received response signal; and a detection unit configured to calculate an evaluation value based on a measurement result obtained by the measurement unit, and detect a partial damage of the transmission line, based on the calculated evaluation value.

A detection system according to the present disclosure includes a detection device and a switching device. The detection device performs a detection process that includes outputting a measurement signal having a frequency component to a transmission line, receiving, from the transmission line, a response signal including a signal in which the measurement signal is reflected, measuring at least one of an amplitude and a phase of the received response signal, calculating an evaluation value based on a measurement result, and detecting a partial damage of the transmission line, based on the calculated evaluation value. The switching device performs a process of switching a state of an end, different from an input end for the measurement signal, of the transmission line, between a normal state where the detection device is allowed to communicate with another device via the transmission line, and a test state where the detection device is allowed to perform the detection process. The switching device can perform, as the process of switching the state of the end to the test state, at least one of a process of switching the state of the end to an open state, a process of switching the state of the end to a short-circuit state, and a process of switching the state of the end to a state of being connected to a load for a test.

A transmission line according to the present disclosure includes a cable part, and a connector part provided at a first end of the cable part. The connector part includes a switching device configured to perform a process of switching the state of the first end between a normal state where communication via the transmission line is allowed, and a test state where a test of the transmission line is allowed. The switching device can perform, as the process of switching the state of the first end to the test state, at least one of a process of switching the state of the first end to an open state, a process of switching the state of the first end to a short-circuit state, and a process of switching the state of the first end to a state of being connected to a load for a test.

A detection method according to the present disclosure is a detection method performed in a detection device, and the method includes: outputting a measurement signal having a frequency component to a transmission line; receiving, from the transmission line, a response signal including a signal in which the measurement signal is reflected, and measuring at least one of an amplitude and a phase of the received response signal; and calculating an evaluation value based on a measurement result of at least one of the amplitude and the phase, and detecting a partial damage of the transmission line, based on the calculated evaluation value.

An aspect of the present disclosure can be realized not only as a detection device including such a characteristic processing unit, but also as a program for causing a computer to execute steps of such characteristic processing, as a semiconductor integrated circuit that realizes a part or the entirety of the detection device, or as a system that includes the detection device.

### BRIEF DESCRIPTION OF DRAWINGS

FIG. 1 shows a configuration of a communication system according to an embodiment of the present disclosure.

FIG. 2 shows an example of a transmission line used in the communication system according to the embodiment of the present disclosure.

FIG. 3 shows a broken transmission line.

FIG. 4 shows a partially broken transmission line.

FIG. 5 shows another example of the transmission line used in the communication system according to the embodiment of the present disclosure.

FIG. 6 shows a partially broken transmission line.

FIG. 7 shows a partially broken transmission line.

FIG. 8 shows a configuration of a detection system according to the embodiment of the present disclosure.

FIG. 9 shows a simulation result of a phase difference pd calculated by a detection unit in a detection device according to the embodiment of the present disclosure.

FIG. 10 shows a simulation result of a phase difference pd calculated by the detection unit in the detection device according to the embodiment of the present disclosure.

FIG. 11 shows an example of a determination table stored in a storage unit in the detection device according to the embodiment of the present disclosure.

FIG. 12 shows a simulation result of an absolute value Arc of a reflection coefficient re calculated by the detection unit in the detection device according to the embodiment of the present disclosure.

FIG. 13 shows an example of a determination table stored in the storage unit in the detection device according to the embodiment of the present disclosure.

FIG. 14 shows a simulation result of a capacitance C calculated by the detection unit in the detection device according to the embodiment of the present disclosure.

FIG. 15 shows a simulation result of a capacitance C calculated by the detection unit in the detection device according to the embodiment of the present disclosure.

FIG. 16 shows an example of a determination table stored in the storage unit in the detection device according to the embodiment of the present disclosure.

FIG. 17 shows a simulation result of an inductance L calculated by the detection unit in the detection device according to the embodiment of the present disclosure.

FIG. 18 shows a simulation result of an inductance L calculated by the detection unit in the detection device according to the embodiment of the present disclosure.

FIG. 19 shows an example of a determination table stored in the storage unit in the detection device according to the embodiment of the present disclosure.

FIG. 20 shows a simulation result of an absolute value AZc of a characteristic impedance Zc calculated by the detection unit in the detection device according to the embodiment of the present disclosure.

FIG. 21 shows a simulation result of an absolute value AZc of a characteristic impedance Zc calculated by the detection unit in the detection device according to the embodiment of the present disclosure.

FIG. 22 shows an example of a determination table stored in the storage unit in the detection device according to the embodiment of the present disclosure.

FIG. 23 is a flowchart showing an example of an operation procedure when a relay device according to the embodiment of the present disclosure performs a detection process.

FIG. 24 shows an example of a sequence of a detection process performed by a detection system according to the embodiment of the present disclosure.

### DETAILED DESCRIPTION

Conventionally, technologies for predicting breakage of transmission lines have been proposed.

### Problems to be Solved by the Present Disclosure

In the technology described in PATENT LITERATURE 1, in order to predict breakage of an electric cable, a breakage detecting line other than the electric cable needs to be used.

The present disclosure has been made to solve the above-described problem, and an object of the present disclosure is to provide a detection device, a detection system, a transmission line, and a detection method which are capable of predicting breakage of a transmission line, with a simple configuration.

### Effects of the Present Disclosure

According to the present disclosure, breakage of a transmission line can be predicated with a simple configuration.

### Description of Embodiment of the Present Disclosure

First, contents of the embodiment of the present disclosure are listed and described.

(1) A detection device according to the embodiment of the present disclosure includes: a signal output unit configured to output a measurement signal having a frequency component to a transmission line; a measurement unit configured to receive, from the transmission line, a response signal including a signal in which the measurement signal is reflected, and measure at least one of an amplitude and a phase of the received response signal; and a detection unit configured to calculate an evaluation value based on a measurement result obtained by the measurement unit, and detect a partial damage of the transmission line, based on the calculated evaluation value.

In the above configuration, the measurement signal having the frequency component is outputted to the transmission line, the evaluation value is calculated based on the measurement result of at least one of the amplitude and the phase of the response signal received from the transmission line, and a partial damage of the transmission line is detected based on the calculated evaluation value. Therefore, a partial damage of the transmission line can be detected without requiring a breakage detecting line other than the transmission line. Consequently, breakage of the transmission line can be predicted with a simple configuration.

(2) In the above (1), the transmission line may include a plurality of strands, and the detection unit may detect, as the partial damage of the transmission line, breakage of some of the plurality of strands.

In the above configuration, an appropriate countermeasure such as replacement of the transmission line can be performed before electrical connection via the transmission line is cut due to breakage of all the strands.

(3) In the above (2), the transmission line includes a core wire in which the plurality of strands are bundled, and the plurality of strands are insulated from each other in a partial area of the core wire.

In the above configuration, the electrical characteristics of the transmission line change more greatly due to a partial damage of the transmission line, as compared to a configuration in which the plurality of strands are conducted with each other in the entire area of the core wire. Thus, a partial damage of the transmission line can be detected more accurately based on the evaluation value.

(4) In any of the above (1) to (3), the detection unit may further detect the degree of damage of the transmission line that is partially damaged.

In the above configuration, a countermeasure such as replacement of the transmission line can be performed at a more appropriate timing according to the degree of damage of the transmission line.

(5) In any of the above (1) to (4), the detection unit may calculate, as the evaluation value, at least one of: a phase difference between the measurement signal and the response signal; a reflection coefficient that is a ratio of an amplitude of the response signal to an amplitude of the measurement signal; an impedance of the transmission line; a reactance of the transmission line; a resistance of the transmission line; a capacitance of the transmission line; an inductance of the transmission line; and a characteristic impedance of the transmission line.

In the above configuration, a partial damage of the transmission line can be detected more accurately based on the evaluation value that changes more greatly due to the partial damage of the transmission line, as compared to a configuration in which, for example, a DC resistance value of the transmission line is calculated as an evaluation value.

(6) A detection system according to the embodiment of the present disclosure includes a detection device and a switching device. The detection device performs a detection process that includes outputting a measurement signal having a frequency component to a transmission line, receiving, from the transmission line, a response signal including a signal in which the measurement signal is reflected, measuring at least one of an amplitude and a phase of the received response signal, calculating an evaluation value based on a measurement result, and detecting a partial damage of the transmission line, based on the calculated evaluation value. The switching device performs a process of switching a state of an end, different from an input end for the measurement signal, of the transmission line, between a normal state where the detection device is allowed to communicate with another device via the transmission line, and a test state where the detection device is allowed to perform the detection process. The process of switching the state of the end to the test state is at least one of a process of switching to a state where the end is open, a process of switching to a state where the end is connected to a ground node, and a process of switching to a state where the end is connected to a load for a test.

In the above configuration, the measurement signal having the frequency component is outputted to the transmission line, the evaluation value is calculated based on the measurement result of at least one of the amplitude and the phase of the response signal received from the transmission line, and a partial damage of the transmission line is detected based on the calculated evaluation value. Therefore, a partial damage of the transmission line can be detected without requiring a breakage detecting line other than the transmission line. In addition, the state of the end of the transmission line is switched to the state where the end is open, the state where the end is connected to a ground node, or the state where the end is connected to a load for a test. Therefore, a partial damage of the transmission line can be detected more accurately based on the more appropriate evaluation value. Consequently, breakage of the transmission line can be predicated with a simple configuration.

(7) A transmission line according to the embodiment of the present disclosure includes a cable part, and a connector part provided at a first end of the cable part. The connector part includes a switching device configured to perform a process of switching a state of the first end between a normal state where communication via the transmission line is allowed, and a test state where a test of the transmission line is allowed. The process of switching the state of the first end to the test state is at least one of a process of switching to a state where the first end is open, a process of switching to a state where the first end is connected to a ground node, and a process of switching to a state where the first end is connected to a load for the test.

In the above configuration, the state of the first end of the cable part is switched to the state where the first end is open, the state where the first end is connected to the ground node, or the state where the first end is connected to the load for the test. Therefore, it is possible to calculate a more appropriate evaluation value based on the characteristics of the transmission line, and more accurately detect, for example, a partial damage of the transmission line, based on the calculated evaluation value. Consequently, breakage of the transmission line can be predicated with a simple configuration.

(8) A detection method according to the embodiment of the present disclosure is a detection method in a detection device, and includes: outputting a measurement signal having a frequency component to a transmission line; receiving, from the transmission line, a response signal including a signal in which the measurement signal is reflected, and measuring at least one of an amplitude and a phase of the received response signal; and calculating an evaluation value based on a measurement result of at least one of the amplitude and the phase, and detecting a partial damage of the transmission line, based on the calculated evaluation value.

In the above method, the measurement signal having the frequency component is outputted to the transmission line, the evaluation value is calculated based on the measurement result of at least one of the amplitude and the phase of the response signal received from the transmission line, and a partial damage of the transmission line is detected based on the calculated evaluation value. Therefore, a partial damage of the transmission line can be detected without requiring a breakage detecting line other than the transmission line. Consequently, breakage of the transmission line can be predicted with a simple configuration.

Hereinafter, an embodiment of the present disclosure will be described with reference to the drawings. In the drawings, the same or corresponding parts are denoted by the same reference signs, and description thereof is not repeated. At least some parts of the embodiment described below may be combined together as desired.

### [Configuration and Basic Operation]

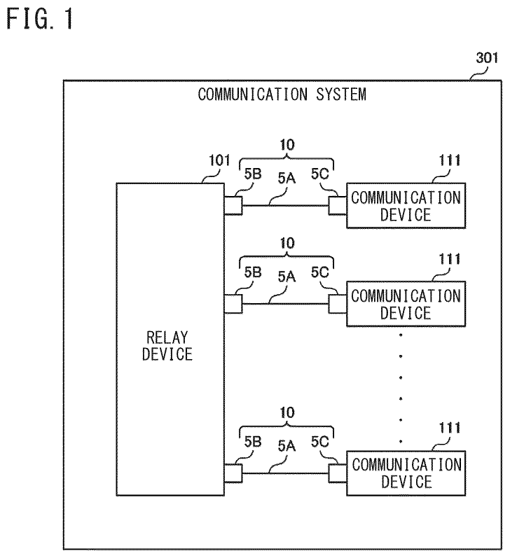

FIG. 1 shows a configuration of a communication system according to the embodiment of the present disclosure. With reference to FIG. 1, a communication system 301 includes a relay device 101 and a plurality of communication devices 111.

The relay device 101 is connected to each communication device 111 on a one-to-one basis via a transmission line 10 for communication. More specifically, the transmission line 10 includes a cable part 5A, and connector parts 5B, 5C provided at a first end and a second end of the cable part 5A. The connector part 5B is connected to the relay device 101. The connector part 5C is connected to the communication device 111. The transmission line 10 is, for example, an Ethernet (registered trademark) cable.

The communication system 301 is installed in a vehicle, for example. In this case, the communication device 111 is an in-vehicle ECU (Electronic Control Unit), for example. The communication system 301 may be used in a home network or factory automation, for example.

The relay device 101 is capable of communicating with the communication devices 111. The relay device 101 performs, for example, a relay process of relaying information being exchanged between the plurality of communication devices 111 connected to different transmission lines 10. In addition, the relay device 101 functions as a detection device, and performs, for example, a detection process of periodically detecting a partial damage of each transmission line 10.

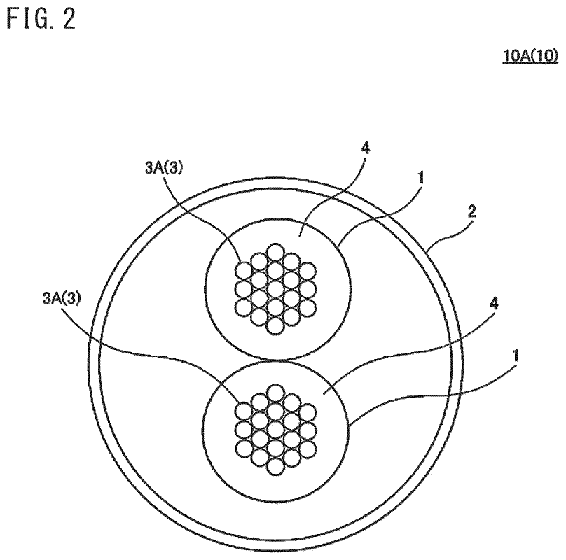

FIG. 2 shows an example of a transmission line used in the communication system according to the embodiment of the present disclosure. FIG. 2 shows a cross-sectional view of a cable part 5A of a transmission line 10A as an example of the transmission line 10. FIG. 2 shows the cross-sectional view of the cable part 5A of the transmission line 10A which is not broken.

With reference to FIG. 2, the transmission line 10A includes two core wires 1 and a sheath 2. A space between the core wires 1 and the sheath 2 may be filled with an insulator. For example, one of the two core wires 1 is a signal line, and the other is a ground line. For example, the transmission line 10A is a twisted pair cable. That is, the two core wires 1 are twisted together. The transmission line 10A may include one core wire 1 or three or more core wires 1, or may be a parallel line in which the plurality of core wires 1 are not twisted together.

In the core wire 1, a plurality of strands 3A as a plurality of strands 3 are bundled. More specifically, the core wire 1 includes a plurality of strands 3A, and an insulating layer 4 that covers the plurality of strands 3A. The plurality of strands 3A in the core wire 1 are electrically conducted with each other in the cable part 5A of the transmission line 10A.

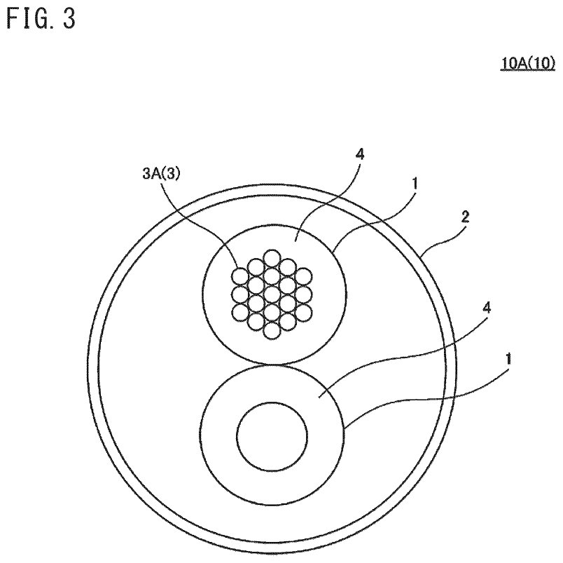

FIG. 3 shows a broken transmission line. FIG. 3 shows a cross-sectional view, at a broken point, of a cable part 5A of a broken transmission line 10A. With reference to FIG. 3, in the broken transmission line 10A, all the strands 3A in the core wire 1 are broken, and electrical connection between the relay device 101 and the communication device 111 at the broken strands 3A is lost. In the state where all the strands 3A in the core wire 1 of the transmission line 10A are broken, the relay device 101 and the communication device 111 are not electrically connected to each other via the core wire 1.

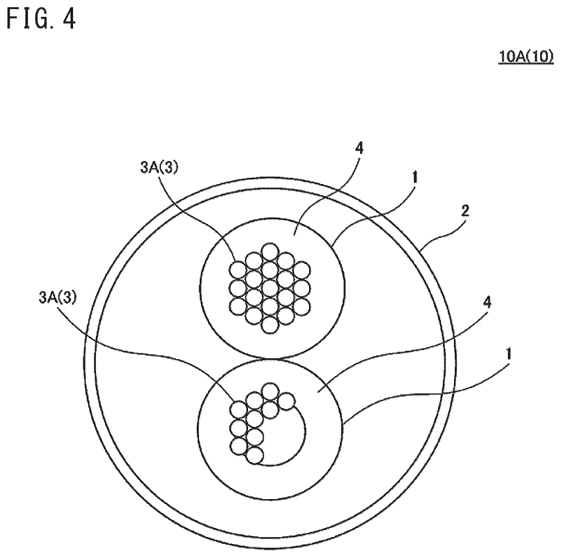

FIG. 4 shows a partially broken transmission line. FIG. 4 shows a cross-sectional view, at a partially broken point, of a cable part 5A of a partially broken transmission line 10A. With reference to FIG. 4, in the partially broken transmission line 10A, some of strands 3A in a core wire 1 are broken, and electrical connection between the relay device 101 and the communication device 111 at the broken strands 3A is lost. Even in the state where some of the strands 3A in the core wire 1 of the transmission line 10A are broken, the relay device 101 and the communication device 111 are electrically connected to each other via the strands 3A that are not broken in the core wire 1. However, if the damage of the transmission line 10A has progressed and reached the state where all the strands 3A in the core wire 1 are broken as shown in FIG. 3, electrical connection between the relay device 101 and the communication device 111 is cut off.

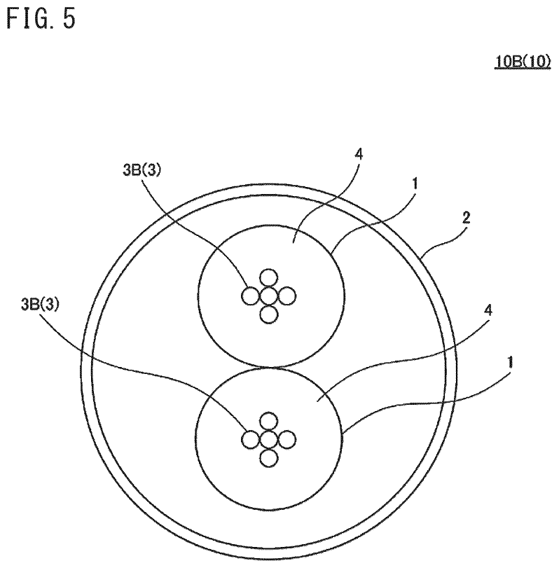

FIG. 5 shows another example of a transmission line used in the communication system according to the embodiment of the present disclosure. FIG. 5 shows a cross-sectional view of a cable part 5A of a transmission line 10B as an example of the transmission line 10. FIG. 5 shows the cross-sectional view of the cable part 5A of the transmission line 10B whose percentage of breakage is 0%. Here, the percentage of breakage of the transmission line 10 is a ratio of broken strands 3 to a plurality of strands 3 in the core wire 1.

With reference to FIG. 5, like the transmission line 10A, the transmission line 10B includes two core wires 1 and a sheath 2. In the core wire 1 of the transmission line 10B, five strands 3B being five strands 3 are bundled. More specifically, the core wire 1 includes five strands 3B, and an insulating layer 4 that covers the five strands 3B.

For example, the five strands 3B in the core wire 1 are insulated from each other in a partial area of the core wire 1. Specifically, the five strands 3B are conducted with each other in the connector parts 5B, 5C of the transmission line 10B, and are insulated from each other in the cable part 5A of the transmission line 10B. More specifically, the five strands 3B are coated with enamel resin or the like, and are insulated from each other in the cable part 5A of the transmission line 10B. The core wire 1 may include one, two, three, four, six or more strands 3B.

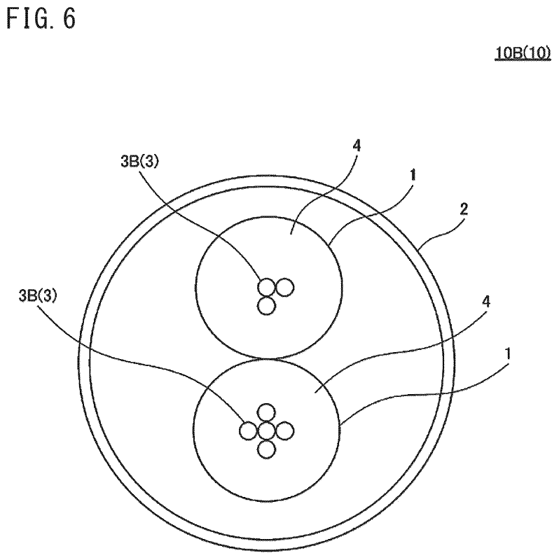

FIG. 6 shows a partially broken transmission line. FIG. 6 is a cross-sectional view, at a partially broken point, of a cable part 5A of a transmission line 10B whose percentage of breakage is 40%. With reference to FIG. 6, in the transmission line 10B whose percentage of breakage is 40%, two strands 3B out of five strands 3B are broken.

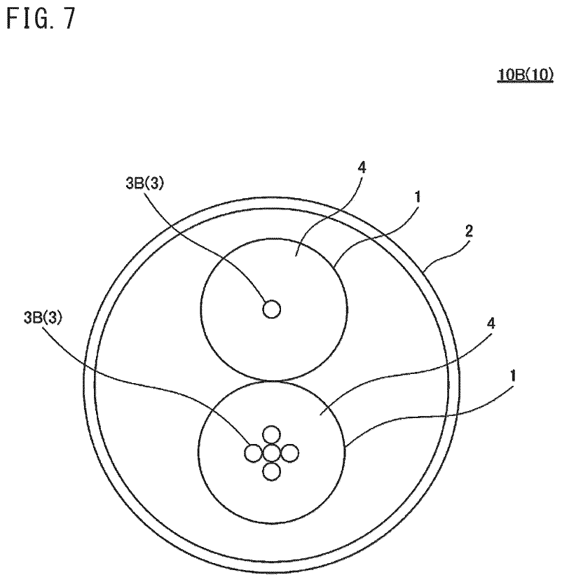

FIG. 7 shows a partially broken transmission line. FIG. 7 is a cross-sectional view, at a partially broken point, of a cable part 5A of a transmission line 10B whose percentage of breakage is 80%. With reference to FIG. 7, in the transmission line 10B whose percentage of breakage is 80%, four strands 3B out of five strands 3B are broken.

In the case where some or all of the strands 3 in the transmission line 10 are broken, the characteristics of the transmission line 10 are changed. For example, the relay device 101 detects, as a partial damage of the transmission line 10, breakage of some of the plurality of strands 3 in the core wire 1 of the transmission line 10.

Also, in the case where some or all of the strands 3 in the transmission line 10 become thin, the characteristics of the transmission line 10 are changed. For example, the relay device 101 detects, as a partial damage of the transmission line 10, thinning of some of the plurality of strands 3 in the core wire 1 of the transmission line 10.

FIG. 3, FIG. 4, FIG. 6, and FIG. 7 each show the cross-sectional view of the cable part 5A of the transmission line 10 in the state where the plurality of strands 3 are broken at the same position in the longitudinal direction of the transmission line 10. However, even when the plurality of strands 3 are broken or become thin at different positions in the longitudinal direction of the transmission line 10, the relay device 101 can detect the breakage or thinning as a partial damage of the transmission line 10.

The core wire 1 of the transmission line 10 may have one strand 3. In this case, the relay device 101 detects thinning of the strand 3 in the core wire 1 of the transmission line 10, as a partial damage of the transmission line 10.

### [Detection System]

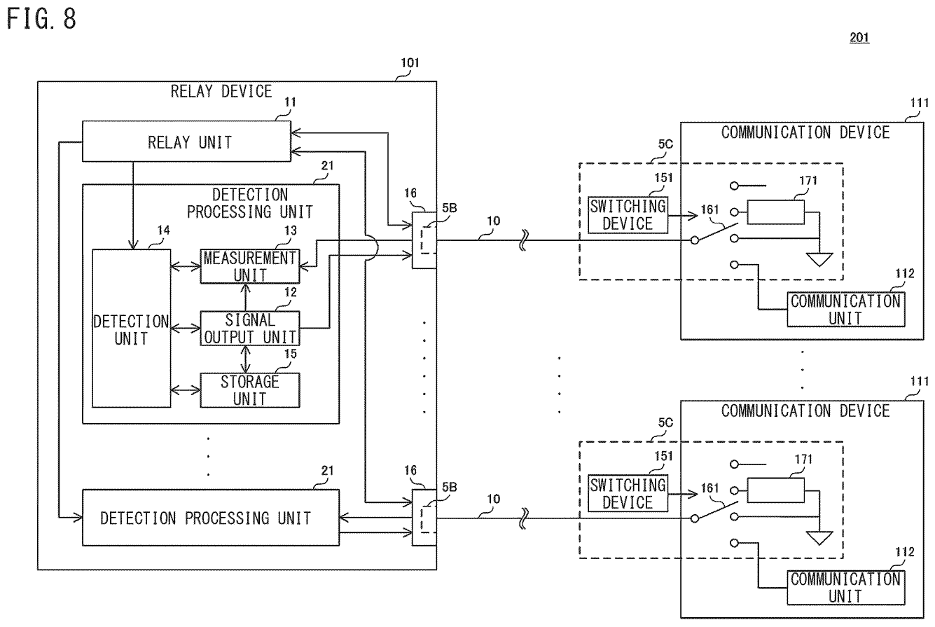

FIG. 8 shows a configuration of a detection system according to the embodiment of the present disclosure. With reference to FIG. 8, a detection system 201 includes the relay device 101, switching devices 151, and switches 161. For example, the connector part 5C of each transmission line 10 includes a switching device 151, a switch 161, and a termination circuit 171. As an example, the termination circuit 171 is a resistor. Instead of the connector part 5C including the switching device 151, the switch 161, and the termination circuit 171, the communication device 111 may include at least one of the switching device 151, the switch 161, and the termination circuit 171.

The relay device 101 outputs a measurement signal having a frequency component to the transmission line 10, and receives, from the transmission line 10, a response signal including a signal in which the measurement signal is reflected. The relay device 101 measures an amplitude and a phase of the received response signal, and calculates an evaluation value EV based on the measurement result. Then, the relay device 101 detects a partial damage of the transmission line 10, based on the calculated evaluation value EV. Details of the processing in the relay device 101 will be described later.

The switching device 151 performs a process of switching the state of an end, different from an input end for the measurement signal, of the transmission line 10, between a normal state where the relay device 101 can communicate with the communication device 111 via the transmission line 10, and a test state where the relay device 101 can perform a detection process. The process of switching the state of the end to the communication state is a process of switching to a state where the end is connected to a communication unit 112 in the communication device 111. The process of switching the state of the end to the test state is at least one of: a process of switching to a state where the end is open; a process of switching to a state where the end is connected to a ground node; and a process of switching to a state where the end is connected to the termination circuit 171. More specifically, by controlling the switch 161, the switching device 151 opens the end, on the communication device 111 side, of the transmission line 10, connects the end to the ground node, or connects the end to the ground node via the termination circuit 171. The termination circuit 171 is an example of a load for the test. The ground node may be a node in a signal return path, or may be a node in a chassis of a structure such as a vehicle in which the communication system 301 is installed. For example, the termination circuit 171 is a resistor of 50Ω that is equal to the characteristic impedance of the transmission line 10, for matching the terminal end of the transmission line 10. The termination circuit 171 may be a load other than the 50Ω resistor, and may not necessarily accurately match the terminal end of the transmission line 10. Hereinafter, the state where the end, on the communication device 111 side, of the transmission line 10 is open is also referred to as “open state”, the state where the end is connected to the ground node is also referred to as “short-circuit state”, and the state where the end is connected to the ground node via the termination circuit 171 is also referred to as “matching state”.

The relay device 101 includes a relay unit 11, a plurality of detection processing units 21, and a plurality of communication ports 16. Each detection processing unit 21 includes a signal output unit 12, a measurement unit 13, a detection unit 14, and a storage unit 15. Some or all of the relay unit 11, the signal output unit 12, the measurement unit 13, and the detection unit 14 are realized by, for example, processing circuitry including one or more processors. The storage unit 15 is, for example, a non-volatile memory included in the processing circuitry. Each communication port 16 is, for example, a connector or a terminal. The connector part 5B of the transmission line 10 is connected to each communication port 16.

### <Relay Unit>

The relay unit 11 performs a relay process. For example, the relay unit 11 performs a relay process of relaying frames between the communication devices 111. More specifically, the relay unit 11 transmits a frame that has been received from a certain communication device 111 via the corresponding transmission line 10 and the corresponding communication port 16, to another communication device 111 via the corresponding communication port 16 and the corresponding transmission line 10, according to destination information such as a destination IP address, a MAC address, a message ID, etc., of the frame.

### <Detection Processing Unit>

For example, the relay device 101 includes the same number of detection processing units 21 as the number of the communication ports 16. More specifically, a detection processing unit 21 is provided so as to correspond to a communication port 16, and performs a detection process of detecting a partial damage of a transmission line 10 connected to the corresponding communication port 16. Hereinafter, the detection process to be performed by one detection processing unit 21 in the relay device 101 will be described as a representative example. A transmission line 10 to be subjected to the detection process of the detection processing unit 21 is also referred to as “target transmission line”. For example, the relay device 101 performs the detection process when the end, on the communication device 111 side, of the target transmission line is in the test state.

### (Signal Output Unit)

The signal output unit 12 outputs a measurement signal having a frequency component to the target transmission line. More specifically, the signal output unit 12 outputs an AC signal, a pulse signal, or a frequency sweep signal, as the measurement signal to the target transmission line.

For example, the signal output unit 12 outputs the measurement signal to the target transmission line via the corresponding communication port 16 in a period during which the relay unit 11 does not perform the relay process via the target transmission line. More specifically, the relay unit 11 outputs, to the detection unit 14, period information indicating the period during which the relay unit 11 does not perform the relay process via the target transmission line.

Upon receiving the period information from the relay unit 11, the detection unit 14 determines a detection period T1 for the detection process, based on the received period information, and outputs a detection instruction indicating the determined detection period T1 to the signal output unit 12 and the measurement unit 13.

The signal output unit 12 receives the detection instruction from the detection unit 14, and when a start time of the detection period T1 indicated by the received detection instruction has arrived, the signal output unit 12 outputs the measurement signal to the target transmission line via the corresponding communication port 16 until the detection period T1 ends.

For example, the storage unit 15 has, stored therein, N digital signals Ds1 obtained by subjecting a predetermined cycle of sine wave to digital conversion. That is, the storage unit 15 has, stored therein, digital signals Ds1 whose number of samples is N and which correspond to the sine wave. Nis an integer not less than 2.

The signal output unit 12 includes a DA (Digital to Analog) converter. When the start time of the detection period T1 has arrived, the signal output unit 12 acquires the digital signal Ds1 from the storage unit 15 at an output timing according to the cycle of an operation clock of the DA converter, and outputs a measurement signal, which is generated by converting the digital signal Ds1 into an analog signal by using the DA converter, to the target transmission line via the communication port 16, until the detection period T1 ends. In addition, the signal output unit 12 outputs the acquired digital signal Ds1 to the detection unit 14 and the measurement unit 13.

The signal output unit 12 may include, for example, a signal generator such as a DDS (Direct Digital Synthesizer), and may output a sine wave generated by the signal generator to the target transmission line via the communication port 16.

### (Measurement Unit)

The measurement unit 13 receives, from the target transmission line, a response signal including a signal in which the measurement signal is reflected, and measures an amplitude and a phase of the received response signal. For example, the measurement unit 13 receives, from the target transmission line via the corresponding communication port 16, the response signal including the measurement signal outputted from the signal output unit 12 and a reflection signal in which the measurement signal is reflected.

More specifically, the measurement unit 13 receives the detection instruction from the detection unit 14, and when the start time of the detection period T1 indicated by the received detection instruction has arrived, the measurement unit 13 receives the response signal from the target transmission line via the corresponding communication port 16 until the detection period T1 ends.

The measurement unit 13 includes an AD (Analog to Digital) converter. During the detection period T1, the measurement unit 13 samples the response signal received from the target transmission line, by using the AD converter, to generate digital signals Ds2 whose number of samples is N.

For example, the measurement unit 13 subtracts the component of the digital signal Ds1 received from the signal output unit 12, from the generated digital signal Ds2, to generate a digital signal Ds3 indicating the reflection signal.

Based on the generated digital signal Ds3, the measurement unit 13 generates amplitude data Ds3a indicating the amplitude of the reflection signal, and phase data Ds3p indicating the phase of the reflection signal, and outputs the generated amplitude data Ds3a and phase data Ds3p to the detection unit 14.

### (Detection Unit)

The detection unit 14 calculates an evaluation value EV based on the measurement result obtained by the measurement unit 13, and detects a partial damage of the target transmission line, based on the calculated evaluation value EV. For example, the detection unit 14 detects, as a partial damage of the target transmission line, breakage of some of a plurality of strands 3 in the core wire 1 of the target transmission line.

In addition, for example, the detection unit 14 further detects the degree of damage of the partially damaged target transmission line. More specifically, the detection unit 14 detects the percentage of breakage of the target transmission line. If the core wire 1 in the target transmission line includes one strand 3, the detection unit 14 detects the degree of thinning of the strand 3.

### (Detection Example 1)

The detection unit 14 calculates a phase difference between a measurement signal and a response signal, as an evaluation value EV. As an example, the detection unit 14 calculates a phase difference pd between the measurement signal and a reflection signal included in the response signal. Based on the calculated phase difference pd, the detection unit 14 detects breakage of some of a plurality of strands 3 in the core wire 1, and the percentage of breakage of the target transmission line.

For example, the detection unit 14 calculates a phase difference pd between the measurement signal and the reflection signal when the measurement signal is outputted to the target transmission line in the open state.

More specifically, when the detection unit 14 has determined a detection period T1, the detection unit 14 transmits, to the switching device 151, a control signal CON_1 for switching the target transmission line to the open state. More specifically, the detection unit 14 transmits the control signal CON_1 to the switching device 151 via a signal line (not shown). Upon receiving the control signal CON_1 from the detection unit 14, the switching device 151 controls the switch 161 according to the received control signal CON_1 to switch the target transmission line to the open state.

With the target transmission line being in the open state, the detection unit 14 outputs a detection instruction to the signal output unit 12 and the measurement unit 13. Then, the detection unit 14 receives a digital signal Ds1 from the signal output unit 12, and generates phase data Ds1p indicating the phase of the measurement signal, based on the received digital signal Ds1.

The detection unit 14 calculates a difference between the phase data Ds3p received from the measurement unit 13 and the calculated phase data Ds1p, for each cycle of the measurement signal. The detection unit 14 calculates a phase difference pd, based on the difference for each cycle of the measurement signal.

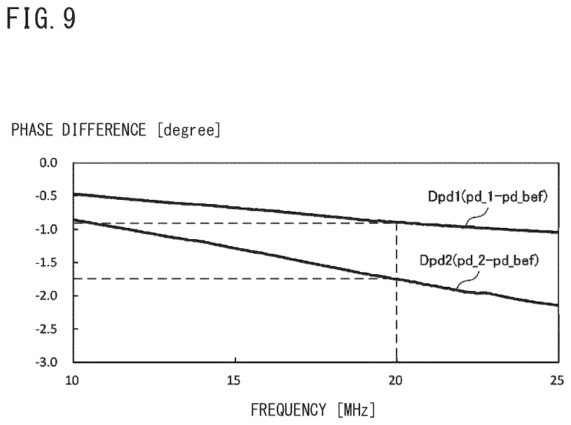

FIG. 9 shows a simulation result of a phase difference pd calculated by the detection unit in the detection device according to the embodiment of the present disclosure. In FIG. 9, the horizontal axis indicates the frequency [MHz] of the measurement signal, and the vertical axis indicates the phase difference [degree]. FIG. 9 shows a difference Dpd1 obtained by subtracting a phase difference pd_bef from a phase difference pd_1, and a difference Dpd2 obtained by subtracting the phase difference pd_bef from a phase difference pd_2. Here, the phase difference pd_bef is a phase difference pd which is calculated by the detection unit 14 when a measurement signal is outputted to a transmission line 10A before being subjected to a bending test. The phase difference pd_1 is a phase difference pd which is calculated by the detection unit 14 when the measurement signal is outputted to the transmission line 10A having been subjected to a bending test BT1. The phase difference pd_2 is a phase difference pd which is calculated by the detection unit 14 when the measurement signal is outputted to the transmission line 10A having been subjected to the bending test BT1 and a subsequent bending test BT2.

Here, the bending tests BT1, BT2 are each a test in which the transmission line 10A is bent by 90 degrees alternately in the positive direction and the negative direction, multiple times. When the inventors of the present disclosure checked a CT (Computed Tomography) image of the transmission line 10A before being subjected to the bending test, none of the strands 3 in the transmission line 10A were broken. When the inventors of the present disclosure checked the CT image of the transmission line 10A which was bent multiple times in the bending test BT1, some of the strands 3 in the transmission line 10A were broken. When the inventors of the present disclosure checked the CT image of the transmission line 10A which was further bent multiple times in the bending test BT2 subsequent to the bending test BT1, more strands 3 were broken as compared to the transmission line 10A which was subjected to the bending test BT1 and was not subjected to the bending test BT2.

With reference to FIG. 9, for example, when the frequency of the measurement signal is 20 MHz, the phase difference pd_1 in the state where some of the strands 3 are broken is about 0.8 degrees different from the phase difference pd_bef in the state where none of the strands 3 are broken. For example, when the frequency of the measurement signal is 20 MHz, the phase difference pd_2 in the state where some of the strands 3 are broken is about 1.7 degrees different from the phase difference pd_bef in the state where none of the strands 3 are broken.

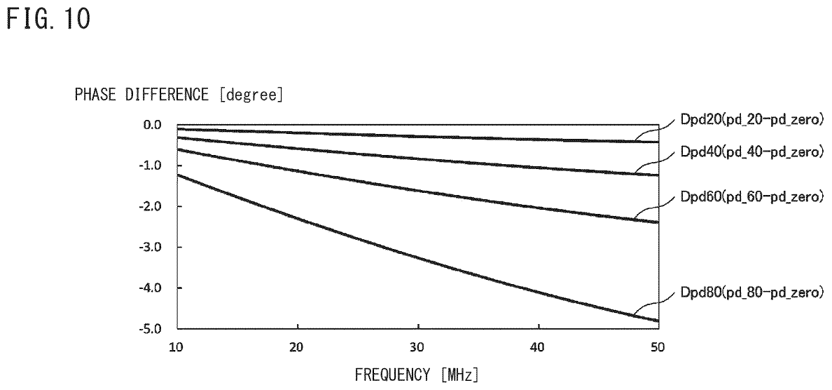

FIG. 10 shows a simulation result of a phase difference pd calculated by the detection unit in the detection device according to the embodiment of the present disclosure. In FIG. 10, the horizontal axis indicates the frequency [MHz] of the measurement signal, and the vertical axis indicates the phase difference [degree]. FIG. 10 shows a difference Dpd20 obtained by subtracting a phase difference pd_zero from a phase difference pd_20, a difference Dpd40 obtained by subtracting the phase difference pd_zero from a phase difference pd_40, a difference Dpd60 obtained by subtracting the phase difference pd_zero from a phase difference pd_60, and a difference Dpd80 obtained by subtracting the phase difference pd_zero from a phase difference pd_80. Here, the phase difference pd_zero is a phase difference pd which is calculated by the detection unit 14 when a measurement signal is outputted to a transmission line 10B whose percentage of breakage is 0%. The phase difference pd_20 is a phase difference pd which is calculated by the detection unit 14 when the measurement signal is outputted to the transmission line 10B whose percentage of breakage is 20%. The phase difference pd_40 is a phase difference pd which is calculated by the detection unit 14 when the measurement signal is outputted to the transmission line 10B whose percentage of breakage is 40%. The phase difference pd_60 is a phase difference pd which is calculated by the detection unit 14 when the measurement signal is outputted to the transmission line 10B whose percentage of breakage is 60%. The phase difference pd_80 is a phase difference pd which is calculated by the detection unit 14 when the measurement signal is outputted to the transmission line 10B whose percentage of breakage is 80%.

With reference to FIG. 10, the differences Dpd20, Dpd40, Dpd60, Dpd80 are arranged in descending order, and are all negative values. That is, the phase difference pd_zero calculated when the percentage of breakage is 0%, the phase difference pd_20 calculated when the percentage of breakage is 20%, the phase difference pd_40 calculated when the percentage of breakage is 40%, the phase difference pd_60 calculated when the percentage of breakage is 60%, and the phase difference pd_80 calculated when the percentage of breakage is 80%, are arranged in descending order.

According to the simulation result described with reference to FIG. 9 and FIG. 10, it is possible to detect whether or not some of the plurality of strands 3 in the core wire 1 of the transmission line 10 are broken, the degree of progress of breakage of the strands 3 in the core wire 1, and the percentage of breakage of the transmission line 10, based on the phase difference pd.

For example, the storage unit 15 has, stored therein, a reference value Spd of the phase difference pd. The reference value Spd is set in advance based on a phase difference pd which is calculated by the detection unit 14 when a measurement signal of a specific frequency is outputted to the target transmission line in which none of the strands 3 are broken. The reference value Spd may be set in advance based on a plurality of phase differences pd which are calculated, when measurement signals of a plurality of specific frequencies are outputted to the target transmission line in which none of the strands 3 are broken, by the detection unit 14 for the respective frequencies of the measurement signals.

After calculating the phase difference pd, the detection unit 14 acquires the reference value Spd from the storage unit 15, and calculates a difference Dpd by subtracting the reference value Spd from the phase difference pd.

For example, the detection unit 14 compares the calculated difference Dpd with a predetermined threshold value Thpd, and determines, based on the comparison result, whether or not some of the plurality of strands 3 in the core wire 1 of the target transmission line are broken. More specifically, the detection unit 14 determines that none of the strands 3 in the core wire 1 are broken, when the difference Dpd is equal to or larger than the threshold value Thpd, whereas the detection unit 14 determines that some of the plurality of strands 3 in the core wire 1 are broken, when the difference Dpd is less than the threshold value Thpd.

For example, the threshold value Thpd is set in advance based on the above-described phase differences pd_bef, pd_1, pd_2.

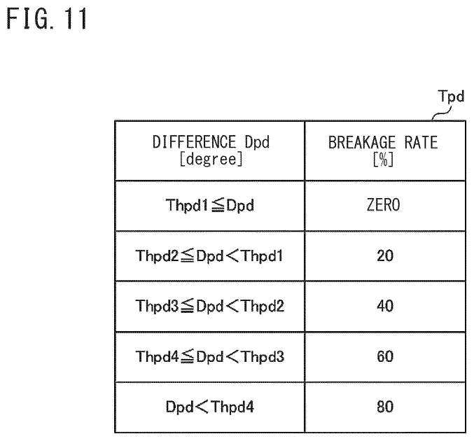

FIG. 11 shows an example of a determination table stored in the storage unit in the detection device according to the embodiment of the present disclosure. With reference to FIG. 11, the storage unit 15 has, stored therein, a determination table Tpd indicating the correspondence between the difference Dpd calculated by the detection unit 14, and the percentage of breakage.

For example, the detection unit 14 determines the percentage of breakage of the target transmission line, based on the calculated difference Dpd, and the determination table Tpd stored in the storage unit 15. More specifically, the detection unit 14 determines that the percentage of breakage is 0% when the difference Dpd is equal to or larger than the threshold value Thpd1. The detection unit 14 determines that the percentage of breakage is 20% when the difference Dpd is equal to or larger than a threshold value Thpd2 and less than the threshold value Thpd1. The detection unit 14 determines that the percentage of breakage is 40% when the difference Dpd is equal to or larger than a threshold value Thpd3 and less than the threshold value Thpd2. The detection unit 14 determines that the percentage of breakage is 60% when the difference Dpd is equal to or larger than a threshold value Thpd4 and less than the threshold value Thpd3. The detection unit 14 determines that the percentage of breakage is 80% when the difference Dpd is less than the threshold value Thpd4.

For example, the threshold values Thpd1, Thpd2, Thpd3, Thpd4 are set in advance based on the above-described phase differences pd_zero, pd_20, pd_40, pd_60, pd_80.

The detection unit 14 may calculate a phase difference pd between the measurement signal and the reflection signal when the measurement signal is outputted to the target transmission line in the matching state or the short-circuit state.

### (Detection Example 2)

The detection unit 14 calculates a reflection coefficient that is a ratio of an amplitude of a response signal to an amplitude of a measurement signal, as an evaluation value EV. As an example, the detection unit 14 calculates a reflection coefficient re which is a ratio of the amplitude of the reflection signal included in the response signal to the amplitude of the measurement signal. Based on the calculated reflection coefficient re, the detection unit 14 detects breakage of some of a plurality of strands 3 in the core wire 1, and the percentage of breakage of the target transmission line.

For example, the detection unit 14 calculates a reflection coefficient rc which is a ratio of the amplitude of the reflection signal to the amplitude of the measurement signal when the measurement signal is outputted to the target transmission line in the matching state.

More specifically, when the detection unit 14 has determined the detection period T1, the detection unit 14 transmits, to the switching device 151, a control signal CON_2 for switching the target transmission line to the matching state. More specifically, the detection unit 14 transmits the control signal CON_2 to the switching device 151 via a signal line (not shown).

Upon receiving the control signal CON_2 from the detection unit 14, the switching device 151 controls the switch 161 according to the received control signal CON_2 to switch the target transmission line to the matching state.

With the target transmission line being in the matching state, the detection unit 14 outputs a detection instruction to the signal output unit 12 and the measurement unit 13. Then, the detection unit 14 receives a digital signal Ds1 from the signal output unit 12, and generates amplitude data Ds1a indicating the amplitude of the measurement signal, based on the received digital signal Ds1.

The detection unit 14 calculates, for each cycle of the measurement signal, a value obtained by dividing the amplitude data Ds3a received from the measurement unit 13 by the generated amplitude data Ds1a. The detection unit 14 calculates a reflection coefficient rc based on the value for each cycle of the measurement signal, and calculates an absolute value Arc of the reflection coefficient rc.

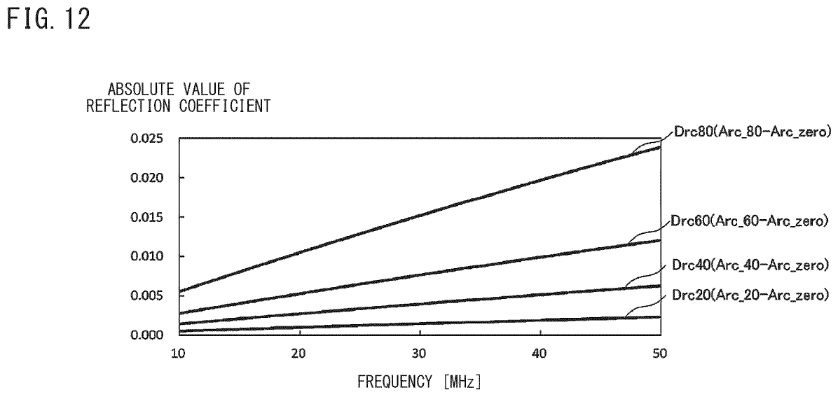

FIG. 12 shows a simulation result of an absolute value Arc of a reflection coefficient re calculated by the detection unit in the detection device according to the embodiment of the present disclosure. In FIG. 12, the horizontal axis indicates the frequency [MHz] of the measurement signal, and the vertical axis indicates the absolute value of the reflection coefficient. FIG. 12 shows a difference Drc20 obtained by subtracting an absolute value Arc_zero from an absolute value Arc_20, a difference Drc40 obtained by subtracting the absolute value Arc_zero from an absolute value Arc_40, a difference Drc60 obtained by subtracting the absolute value Arc_zero from an absolute value Arc_60, and a difference Drc80 obtained by subtracting the absolute value Arc_zero from an absolute value Arc 80. Here, the absolute value Arc_zero is an absolute value Arc of a reflection coefficient rc which is calculated by the detection unit 14 when a measurement signal is outputted to a transmission line 10B whose percentage of breakage is 0%. The absolute value Arc_20 is an absolute value Arc of a reflection coefficient re which is calculated by the detection unit 14 when the measurement signal is outputted to the transmission line 10B whose percentage of breakage is 20%. The absolute value Arc_40 is an absolute value Arc of a reflection coefficient re which is calculated by the detection unit 14 when the measurement signal is outputted to the transmission line 10B whose percentage of breakage is 40%. The absolute value Arc 60 is an absolute value Arc of a reflection coefficient rc which is calculated by the detection unit 14 when the measurement signal is outputted to the transmission line 10B whose percentage of breakage is 60%. The absolute value Arc_80 is an absolute value Arc of a reflection coefficient rc which is calculated by the detection unit 14 when the measurement signal is outputted to the transmission line 10B whose percentage of breakage is 80%.

With reference to FIG. 12, the differences Dpd80, Dpd60, Dpd40, Dpd20 are arranged in descending order, and are all positive values. That is, the absolute value Arc_80 calculated when the percentage of breakage is 80%, the absolute value Arc_60 calculated when the percentage of breakage is 60%, the absolute value Arc_40 calculated when the percentage of breakage is 40%, the absolute value Arc_20 calculated when the percentage of breakage is 20%, and the absolute value Arc_zero calculated when the percentage of breakage is 0%, are arranged in descending order.

According to the simulation result described with reference to FIG. 12, it is possible to detect whether or not some of the plurality of strands 3 in the core wire 1 of the transmission line 10 are broken, the degree of progress of breakage of the strands 3 in the core wire 1, and the percentage of breakage of the transmission line 10, based on the absolute value Arc of the reflection coefficient rc.

For example, the storage unit 15 has, stored therein, a reference value Src of the reflection coefficient rc. The reference value Src is set in advance based on an absolute value Arc which is calculated by the detection unit 14 when a measurement signal of a specific frequency is outputted to the target transmission line in which none of the strands 3 are broken. The reference value Src may be set in advance based on a plurality of absolute values Arc which are calculated, when measurement signals of a plurality of specific frequencies are outputted to the target transmission line in which none of the strands 3 are broken, by the detection unit 14 for the respective frequencies of the measurement signals.

After calculating the absolute value Arc, the detection unit 14 acquires the reference value Src from the storage unit 15, and calculates a difference Dre by subtracting the reference value Src from the absolute value Arc.

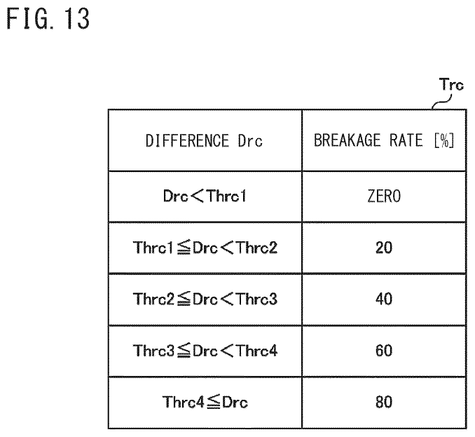

FIG. 13 shows an example of a determination table stored in the storage unit in the detection device according to the embodiment of the present disclosure. With reference to FIG. 13, the storage unit 15 has, stored therein, a determination table Trc indicating the correspondence between the difference Dre calculated by the detection unit 14, and the percentage of breakage.

For example, the detection unit 14 determines the percentage of breakage of the target transmission line, based on the calculated difference Drc, and the determination table Trc stored in the storage unit 15. More specifically, the detection unit 14 determines that the percentage of breakage is 0% when the difference Dre is less than a threshold value Thrc1. The detection unit 14 determines that the percentage of breakage is 20% when the difference Drc is equal to or larger than the threshold value Thrc1 and less than a threshold value Thrc2. The detection unit 14 determines that the percentage of breakage is 40% when the difference Dre is equal to or larger than the threshold value Thrc2 and less than a threshold value Thrc3. The detection unit 14 determines that the percentage of breakage is 60% when the difference Dre is equal to or larger than the threshold value Thrc3 and less than a threshold value Thrc4. The detection unit 14 determines that the percentage of breakage is 80% when the difference Dre is equal to or larger than the threshold value Thrc4.

For example, the threshold values Thrc1, Thrc2, Thrc3, Thrc4 are set in advance based on the above-described absolute values Arc_zero, Arc_20, Arc_40, Arc_60, Arc_80.

The detection unit 14 may calculate a reflection coefficient re between the measurement signal and the reflection signal, and an absolute value Arc, when the measurement signal is outputted to the target transmission line in the open state or the short-circuit state.

### (Detection Example 3)

The detection unit 14 calculates an impedance Z of the target transmission line, as an evaluation value EV. Based on the calculated impedance Z, the detection unit 14 detects breakage of some of a plurality of strands 3 in the core wire 1, and the percentage of breakage of the target transmission line.

For example, the detection unit 14 calculates an impedance Z of the target transmission line in the matching state.

More specifically, the detection unit 14 calculates a reflection coefficient re by performing the process described in detection example 2. Then, the detection unit 14 calculates an impedance Z according to the following formula (1).

### [Math. 1]

$$Z = \frac{1 + rc}{1 - rc} \times Zout \qquad ( 1 )$$

In formula (1), Zout is an output impedance of the relay device 101. For example, the output impedance Zout is stored in the storage unit 15 in advance.

After calculating the reflection coefficient re, the detection unit 14 acquires the output impedance Zout from the storage unit 15, and calculates the impedance Z according to formula (1).

For example, the storage unit 15 has, stored therein, a reference value SZ of the impedance Z. The reference value SZ is set in advance based on an impedance Z which is calculated by the detection unit 14 when a measurement signal of a specific frequency is outputted to the target transmission line in which none of the strands 3 are broken. The reference value SZd may be set in advance based on a plurality of impedances Z which are calculated, when measurement signals of a plurality of specific frequencies are outputted to the target transmission line in which none of the strands 3 are broken, by the detection unit 14 for the respective frequencies of the measurement signals.

After calculating the impedance Z, the detection unit 14 acquires the reference value SZ from the storage unit 15, and calculates a difference DZ by subtracting the reference value SZ from the acquired impedance Z.

For example, based on the calculated difference DZ, the detection unit 14 determines whether or not some of the plurality of strands 3 in the core wire 1 of the target transmission line are broken, and the percentage of breakage, at the core wire 1, of the target transmission line.

The detection unit 14 may calculate an impedance Z of the target transmission line in the open state or the short-circuit state.

### (Detection Example 4)

The detection unit 14 calculates a reactance X of the target transmission line, as an evaluation value EV. Based on the calculated reactance X, the detection unit 14 detects breakage of some of a plurality of strands 3 in the core wire 1, and the percentage of breakage of the target transmission line.

For example, the detection unit 14 calculates a reactance X of the target transmission line in the matching state.

More specifically, the detection unit 14 calculates an impedance Z by performing the process described in detection example 3. Then, the detection unit 14 acquires a reactance X which is an imaginary part of the impedance Z.

For example, the storage unit 15 has, stored therein, a reference value SX of the reactance X. The reference value SX is set in advance based on a reactance X which is calculated by the detection unit 14 when a measurement signal of a specific frequency is outputted to the target transmission line in which none of the strands 3 are broken. The reference value SX may be set in advance based on a plurality of reactances X which are calculated, when measurement signals of a plurality of specific frequencies are outputted to the target transmission line in which none of the strands 3 are broken, by the detection unit 14 for the respective frequencies of the measurement signals.

After calculating the reactance X, the detection unit 14 acquires the reference value SX from the storage unit 15, and calculates a difference DX by subtracting the reference value SX from the reactance X.

For example, based on the calculated difference DX, the detection unit 14 determines whether or not some of the plurality of strands 3 in the core wire 1 of the target transmission line are broken, and the percentage of breakage, at the core wire 1, of the target transmission line.

The detection unit 14 may calculate a reactance X of the target transmission line in the open state or the short-circuit state.

### (Detection Example 5)

The detection unit 14 calculates a resistance R of the target transmission line, as an evaluation value EV. Based on the calculated resistance R, the detection unit 14 detects breakage of some of a plurality of strands 3 in the core wire 1, and the percentage of breakage of the target transmission line.

For example, the detection unit 14 calculates a resistance R of the target transmission line in the matching state.

More specifically, the detection unit 14 calculates an impedance Z by performing the process described in detection example 3. Then, the detection unit 14 acquires a resistance R which is a real part of the impedance Z.

For example, the storage unit 15 has, stored therein, a reference value SR of the resistance R. The reference value SR is set in advance based on a resistance R which is calculated by the detection unit 14 when a measurement signal of a specific frequency is outputted to the target transmission line in which none of the strands 3 are broken. The reference value SR may be set in advance based on a plurality of resistances R which are calculated, when measurement signals of a plurality of specific frequencies are outputted to the target transmission line in which none of the strands 3 are broken, by the detection unit 14 for the respective frequencies of the measurement signals.

After calculating the resistance R, the detection unit 14 acquires the reference value SR from the storage unit 15, and calculates a difference DR by subtracting the reference value SR from the resistance R.

For example, based on the calculated difference DR, the detection unit 14 determines whether or not some of the plurality of strands 3 in the core wire 1 of the target transmission line are broken, and the percentage of breakage, at the core wire 1, of the target transmission line.

The detection unit 14 may calculate a resistance R of the target transmission line in the open state or the short-circuit state.

### (Detection Example 6)

The detection unit 14 calculates a capacitance C of the target transmission line, as an evaluation value EV. Based on the calculated capacitance C, the detection unit 14 detects breakage of some of a plurality of strands 3 in the core wire 1, and the percentage of breakage of the target transmission line.

For example, the detection unit 14 calculates a capacitance C in the target transmission line in the open state.

More specifically, when the detection unit 14 has determined a detection period T1, the detection unit 14 transmits, to the switching device 151, a control signal CON_1 for switching the target transmission line to the open state. More specifically, the detection unit 14 transmits the control signal CON_1 to the switching device 151 via a signal line (not shown).

Upon receiving the control signal CON_1 from the detection unit 14, the switching device 151 controls the switch 161 according to the received control signal CON_1 to switch the target transmission line to the open state.

With the target transmission line being in the open state, the detection unit 14 outputs a detection instruction to the signal output unit 12 and the measurement unit 13. Then, the detection unit 14 calculates an impedance Z by performing the process described in detection example 3.

Hereinafter, the impedance Z of the target transmission line in the open state is referred to as an impedance Zop. The impedance Zop is represented by the following formula (2).

### [Math. 2]

$$Zop = \frac{1}{G + j ω C} \qquad ( 2 )$$

In formula (2), G is the conductance of the target detection line, j is an imaginary unit, and o is an angular velocity [rad/sec].

After calculating the impedance Zop, the detection unit 14 acquires a capacitance C from an imaginary part of the impedance Zop.

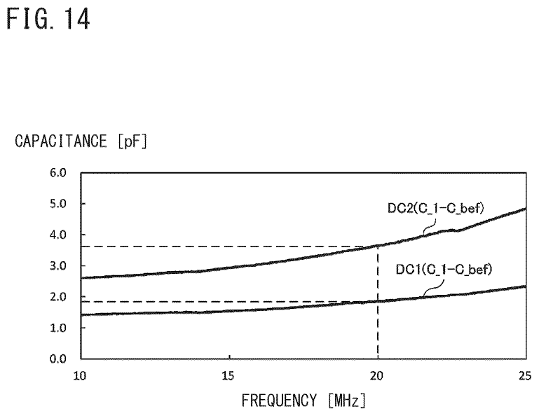

FIG. 14 shows a simulation result of a capacitance C calculated by the detection unit in the detection device according to the embodiment of the present disclosure. In FIG. 14, the horizontal axis indicates the frequency [MHz] of the measurement signal, and the vertical axis indicates the capacitance [pF]. FIG. 14 shows a difference DC1 obtained by subtracting a capacitance C_bef from a capacitance C_1, and a difference DC2 obtained by subtracting the capacitance C_bef from a capacitance C_2. Here, the capacitance C_bef is a capacitance C which is calculated by the detection unit 14 when a measurement signal is outputted to a transmission line 10A before being subjected to a bending test. The capacitance C_1 is a capacitance C which is calculated by the detection unit 14 when the measurement signal is outputted to the transmission line 10A having been subjected to a bending test BT1. The capacitance C_2 is a capacitance C which is calculated by the detection unit 14 when the measurement signal is outputted to the transmission line 10A having been subjected to the bending test BT1 and a subsequent bending test BT2.

With reference to FIG. 14, for example, when the frequency of the measurement signal is 20 MHz, the capacitance C_1 in the state where some of the strands 3 are broken is about 1.9 pF larger than the capacitance C_bef in the state where none of the strands 3 are broken. For example, when the frequency of the measurement signal is 20 MHz, the capacitance C_2 in the state where some of the strands 3 are broken is about 3.6 pF larger than the capacitance C_bef in the state where none of the strands 3 are broken.

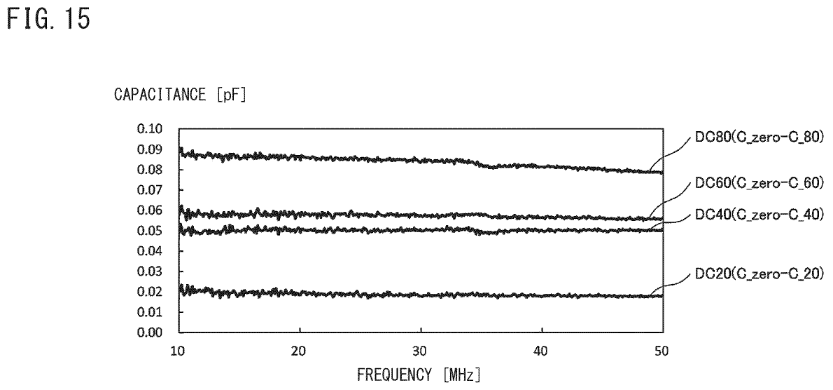

FIG. 15 shows a simulation result of a capacitance C calculated by the detection unit in the detection device according to the embodiment of the present disclosure. In FIG. 15, the horizontal axis indicates the frequency [MHz] of the measurement signal, and the vertical axis indicates the capacitance [pF]. FIG. 15 shows a difference DC20 obtained by subtracting a capacitance C_20 from a capacitance C_zero, a difference DC40 obtained by subtracting a capacitance C_40 from the capacitance C_zero, a difference DC60 obtained by subtracting a capacitance C_60 from the capacitance C_zero, and a difference DC80 obtained by subtracting a capacitance C_80 from the capacitance C_zero. Here, the capacitance C_zero is a capacitance C which is calculated by the detection unit 14 when a measurement signal is outputted to a transmission line 10B whose percentage of breakage is 0%. The capacitance C_20 is a capacitance C which is calculated by the detection unit 14 when the measurement signal is outputted to the transmission line 10B whose percentage of breakage is 20%. The capacitance C_40 is a capacitance C which is calculated by the detection unit 14 when the measurement signal is outputted to the transmission line 10B whose percentage of breakage is 40%. The capacitance C_60 is a capacitance C which is calculated by the detection unit 14 when the measurement signal is outputted to the transmission line 10B whose percentage of breakage is 60%. The capacitance C_80 is a capacitance C which is calculated by the detection unit 14 when the measurement signal is outputted to the transmission line 10B whose percentage of breakage is 80%.

With reference to FIG. 15, the differences DC80, DC60, DC40, DC20 are arranged in descending order, and are all positive values. That is, the capacitance C_zero calculated when the percentage of breakage is 0%, the capacitance C_20 calculated when the percentage of breakage is 20%, the capacitance C_40 calculated when the percentage of breakage is 40%, the capacitance C_60 calculated when the percentage of breakage is 60%, and the capacitance C_80 calculated when the percentage of breakage is 80%, are arranged in descending order.

According to the simulation result described with reference to FIG. 14 and FIG. 15, it is possible to determine, based on the capacitance C, whether or not some of the plurality of strands 3 in the core wire 1 of the transmission line 10 are broken, the degree of progress of breakage of the strands 3 in the core wire 1, and the percentage of breakage of the transmission line 10.

For example, the storage unit 15 has, stored therein, a reference value SC of the capacitance C. The reference value SC is set in advance based on a capacitance C which is calculated by the detection unit 14 when a measurement signal of a specific frequency is outputted to the target transmission line in which none of the strands 3 are broken. The reference value SC may be set in advance based on a plurality of capacitances C which are calculated, when measurement signals of a plurality of specific frequencies are outputted to the target transmission line in which none of the strands 3 are broken, by the detection unit 14 for the respective frequencies of the measurement signals.

After calculating the capacitance C, the detection unit 14 acquires the reference value SC from the storage unit 15, and calculates a difference DCa by subtracting the reference value SC from the capacitance C.

For example, the detection unit 14 compares the calculated difference DCa with a predetermined threshold value ThC, and determines, based on the comparison result, whether or not some of the plurality of strands 3 in the core wire 1 of the target transmission line are broken. More specifically, the detection unit 14 determines that none of the strands 3 in the core wire 1 are broken, when the difference DCa is less than the threshold value ThC, whereas the detection unit 14 determines that some of the plurality of strands 3 in the core wire 1 are broken, when the difference DCa is equal to or larger than the threshold value ThC.

For example, the threshold value ThC is set in advance based on the capacitances C_bef, C_1, C_2.

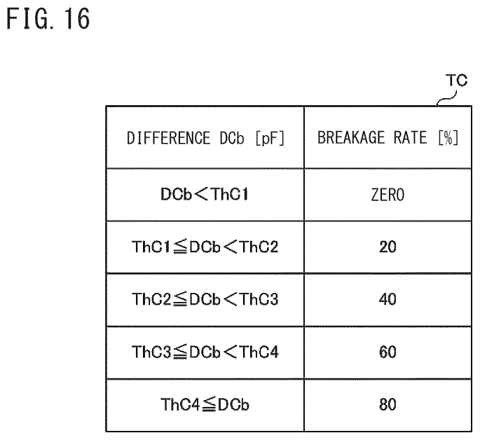

FIG. 16 shows an example of a determination table stored in the storage unit in the detection device according to the embodiment of the present disclosure. With reference to FIG. 16, the storage unit 15 has, stored therein, a determination table TC indicating the correspondence between a difference DCb calculated by the detection unit 14, and the percentage of breakage.

For example, after calculating the capacitance C, the detection unit 14 acquires the reference value SC from the storage unit 15, and calculates a difference DCb by subtracting the capacitance C from the reference value SC. The detection unit 14 determines the percentage of breakage of the target transmission line, based on the calculated difference DCb, and the determination table TC stored in the storage unit 15. More specifically, the detection unit 14 determines that the percentage of breakage is 0% when the difference DCb is less than a threshold value ThC1. The detection unit 14 determines that the percentage of breakage is 20% when the difference DCb is equal to or larger than the threshold value ThC1 and less than a threshold value ThC2. The detection unit 14 determines that the percentage of breakage is 40% when the difference DCb is equal to or larger than the threshold value ThC2 and less than a threshold value ThC3. The detection unit 14 determines that the percentage of breakage is 60% when the difference DCb is equal to or larger than the threshold value ThC3 and less than a threshold value ThC4. The detection unit 14 determines that the percentage of breakage is 80% when the difference DCb is equal to or larger than the threshold value ThC4.

For example, the threshold values ThC1, ThC2, ThC3, ThC4 are set in advance based on the above-described capacitances C_zero, C_20, C_40, C_60, C_80.

### (Detection Example 7)

The detection unit 14 calculates an inductance L of the target transmission line, as an evaluation value EV. Based on the calculated inductance L, the detection unit 14 detects breakage of some of a plurality of strands 3 in the core wire 1, and the percentage of breakage of the target transmission line.

For example, the detection unit 14 calculates an inductance L of the target transmission line in the short-circuit state.

More specifically, when the detection unit 14 has determined a detection period T1, the detection unit 14 transmits, to the switching device 151, a control signal CON_3 for switching the target transmission line to the short-circuit state. More specifically, the detection unit 14 transmits the control signal CON_3 to the switching device 151 via a signal line (not shown).

Upon receiving the control signal CON_3 from the detection unit 14, the switching device 151 controls the switch 161 according to the received control signal CON_3 to switch the target transmission line to the short-circuit state.

With the target transmission line being in the short-circuit state, the detection unit 14 outputs a detection instruction to the signal output unit 12 and the measurement unit 13. Then, the detection unit 14 calculates an impedance Z by performing the process described in detection example 3.

Hereinafter, the impedance Z of the target transmission line in the short-circuit state is referred to as an impedance Zst. The impedance Zst is represented by the following formula (3).

### [Math. 3]

$$Zst = R + j ω L \qquad ( 3 )$$

In formula (3), R is a DC resistance [Ω] per unit length of the target transmission line.

After calculating the impedance Zst, the detection unit 14 acquires an inductance L from an imaginary part of the impedance Zst.

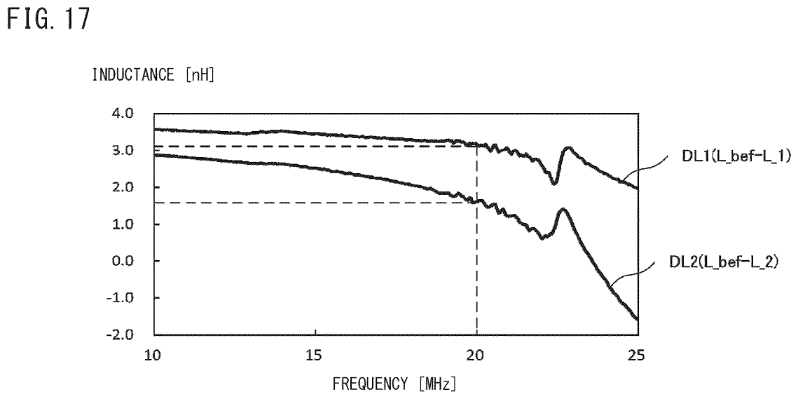

FIG. 17 shows a simulation result of an inductance L calculated by the detection unit in the detection device according to the embodiment of the present disclosure. In FIG. 17, the horizontal axis indicates the frequency [MHz] of the measurement signal, and the vertical axis indicates the inductance [nH]. FIG. 17 shows a difference DL1 obtained by subtracting an inductance L_1 from an inductance L_bef, and a difference DL2 obtained by subtracting an inductance L_2 from the inductance L_bef. Here, the inductance L_bef is an inductance L which is calculated by the detection unit 14 when a measurement signal is outputted to a transmission line 10A before being subjected to a bending test. The inductance L_1 is an inductance L which is calculated by the detection unit 14 when the measurement signal is outputted to the transmission line 10A having been subjected to a bending test BT1. The inductance L_2 is an inductance L which is calculated by the detection unit 14 when the measurement signal is outputted to the transmission line 10A having been subjected to the bending test BT1 and a subsequent bending test BT2.

With reference to FIG. 17, for example, when the frequency of the measurement signal is 20 MHz, the inductance L_2 in the state where some of the strands 3 are broken is about 1.5 nH smaller than the inductance L_bef in the state where none of the strands 3 are broken. For example, when the frequency of the measurement signal is 20 MHz, the inductance L_1 in the state where some of the strands 3 are broken is about 3.1 nH smaller than the inductance L_bef in the state where none of the strands 3 are broken.

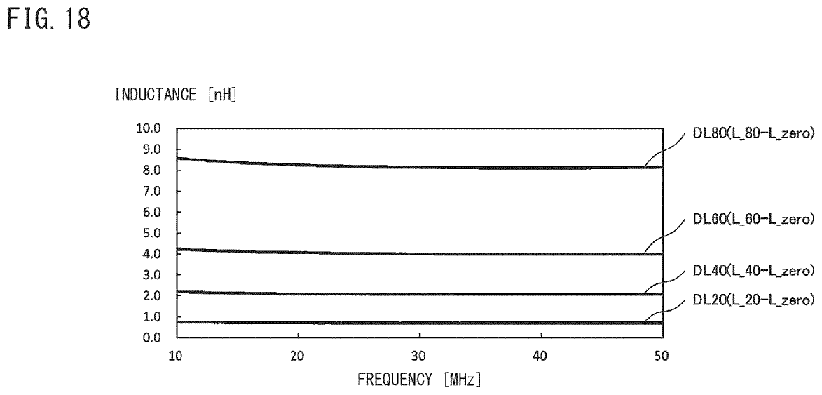

FIG. 18 shows a simulation result of an inductance L calculated by the detection unit in the detection device according to the embodiment of the present disclosure. In FIG. 18, the horizontal axis indicates the frequency [MHz] of the measurement signal, and the vertical axis indicates the inductance [nH]. FIG. 18 shows a difference DL20 obtained by subtracting an inductance L_zero from an inductance L_20, a difference DL40 obtained by subtracting the inductance L_zero from an inductance L_40, a difference DL60 obtained by subtracting the inductance L_zero from an inductance L_60, and a difference DL80 obtained by subtracting the inductance L_zero from an inductance L_80. Here, the inductance L_zero is an inductance L which is calculated by the detection unit 14 when a measurement signal is outputted to a transmission line 10B whose percentage of breakage is 0%. The inductance L_20 is an inductance L which is calculated by the detection unit 14 when the measurement signal is outputted to the transmission line 10B whose percentage of breakage is 20%. The inductance L_40 is an inductance L which is calculated by the detection unit 14 when the measurement signal is outputted to the transmission line 10B whose percentage of breakage is 40%. The inductance L_60 is an inductance L which is calculated by the detection unit 14 when the measurement signal is outputted to the transmission line 10B whose percentage of breakage is 60%. The inductance L_80 is an inductance L which is calculated by the detection unit 14 when the measurement signal is outputted to the transmission line 10B whose percentage of breakage is 80%.

With reference to FIG. 18, the differences DL80, DL60, DL40, DL20 are arranged in descending order, and are all positive values. That is, the inductance L_80 calculated when the percentage of breakage is 80%, the inductance L_60 calculated when the percentage of breakage is 60%, the inductance L_40 calculated when the percentage of breakage is 40%, the inductance L_20 calculated when the percentage of breakage is 20%, and the inductance L_zero calculated when the percentage of breakage is 0%, are arranged in descending order.

According to the simulation result described with reference to FIG. 17 and FIG. 18, it is possible to determine, based on the inductance L, whether or not some of the plurality of strands 3 in the core wire 1 of the transmission line 10 are broken, the degree of progress of breakage of the strands 3 in the core wire 1, and the percentage of breakage of the transmission line 10.

For example, the storage unit 15 has, stored therein, a reference value SL of the inductance L. The reference value SL is set in advance based on an inductance L which is calculated by the detection unit 14 when a measurement signal of a specific frequency is outputted to the target transmission line in which none of the strands 3 are broken. The reference value SL may be set in advance based on a plurality of inductances L which are calculated, when measurement signals of a plurality of specific frequencies are outputted to the target transmission line in which none of the strands 3 are broken, by the detection unit 14 for the respective frequencies of the measurement signals.

After calculating the inductance L, the detection unit 14 acquires the reference value SL from the storage unit 15, and calculates a difference DLa by subtracting the inductance L from the reference value SL.

For example, the detection unit 14 compares the calculated difference DLa with a predetermined threshold value ThL, and determines, based on the comparison result, whether or not some of the plurality of strands 3 in the core wire 1 of the target transmission line are broken. More specifically, the detection unit 14 determines that none of the strands 3 in the core wire 1 are broken, when the difference DLa is equal to or larger than the threshold value ThL, whereas the detection unit 14 determines that some of the plurality of strands 3 in the core wire 1 are broken, when the difference DLa is less than the threshold value ThL.

For example, the threshold value ThL is set in advance based on the above-described inductances L_bef, L_1, L_2.

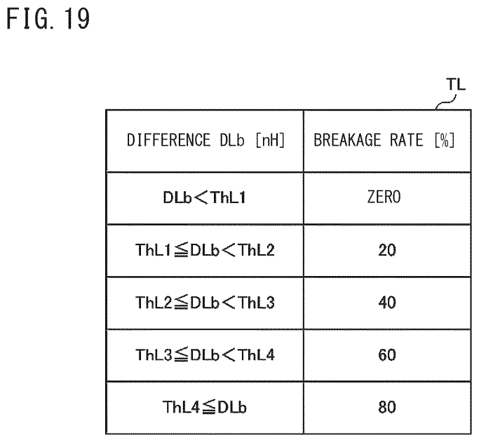

FIG. 19 shows an example of a determination table stored in the storage unit in the detection device according to the embodiment of the present disclosure. With reference to FIG. 19, the storage unit 15 has, stored therein, a determination table TL indicating the correspondence between a difference DLb calculated by the detection unit 14 and the percentage of breakage.

For example, after calculating the inductance L, the detection unit 14 acquires the reference value SL from the storage unit 15, and calculates a difference DLb by subtracting the reference value SL from the inductance L. The detection unit 14 determines the percentage of breakage of the target transmission line, based on the calculated difference DLb, and the determination table TL stored in the storage unit 15. More specifically, the detection unit 14 determines that the percentage of breakage is 0% when the difference DLb is less than a threshold value ThL1. The detection unit 14 determines that the percentage of breakage is 20% when the difference DLb is equal to or larger than the threshold value ThL_1 and less than a threshold value ThL2. The detection unit 14 determines that the percentage of breakage is 40% when the difference DLb is equal to or larger than the threshold value ThL2 and less than a threshold value ThL3. The detection unit 14 determines that the percentage of breakage is 60% when the difference DLb is equal to or larger than the threshold value ThL3 and less than a threshold value ThL4. The detection unit 14 determines that the percentage of breakage is 80% when the difference DLb is equal to or larger than the threshold value ThL4.

For example, the threshold values ThL1, ThL2, ThL3, ThL4 are set in advance based on the above-described inductances L_zero, L_20, L_40, L_60, L_80.

### (Detection Example 8)

The detection unit 14 calculates a characteristic impedance Zc of the target transmission line, as an evaluation value EV. Based on the calculated characteristic impedance Zc, the detection unit 14 detects breakage of some of a plurality of strands 3 in the core wire 1, and the percentage of breakage of the target transmission line.

For example, the detection unit 14 calculates a characteristic impedance Zc of the target transmission line in the open state and the short-circuit state.

More specifically, the detection unit 14 calculates an impedance Zop by performing the process described in detection example 6. Next, the detection unit 14 calculates an impedance Zst by performing the process described in detection example 7. The detection unit 14 may calculate the impedance Zst first, and then calculate the impedance Zop.

Then, the detection unit 14 calculates a characteristic impedance Zc according to the following formula (4), and calculates an absolute value AZc of the characteristic impedance Zc.

### [Math. 4]

$$Zc = \sqrt{Zop \times Zst} \qquad ( 4 )$$

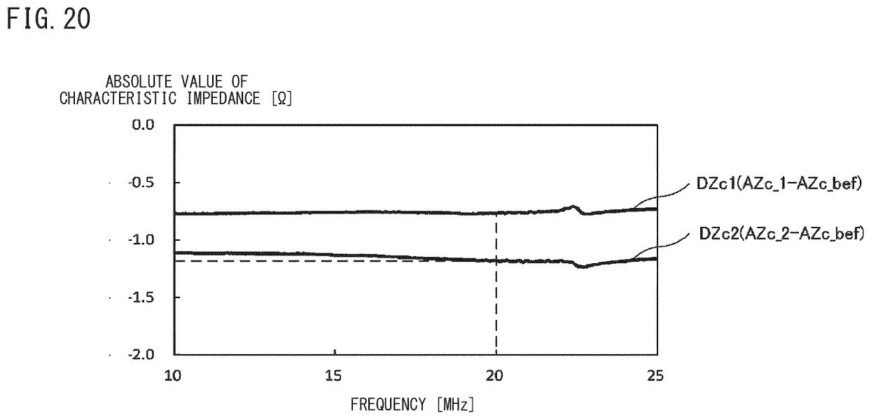

FIG. 20 shows a simulation result of an absolute value AZc of a characteristic impedance Zc calculated by the detection unit in the detection device according to the embodiment of the present disclosure. In FIG. 20, the horizontal axis indicates the frequency [MHz] of the measurement signal, and the vertical axis indicates the absolute value [2] of the characteristic impedance. FIG. 20 indicates a difference DZc1 obtained by subtracting an absolute value AZc_bef from an absolute value AZc 1, and a difference DZc2 obtained by subtracting the absolute value AZc_bef from an absolute value AZc 2. Here, the absolute value AZc_bef is an absolute value AZc of a characteristic impedance Zc which is calculated by the detection unit 14 when a measurement signal is outputted to a transmission line 10A before being subjected to a bending test. The absolute value AZc 1 is an absolute value AZc of a characteristic impedance Zc which is calculated by the detection unit 14 when the measurement signal is outputted to the transmission line 10A having been subjected to a bending test BT1. The absolute value AZc_2 is an absolute value AZc of a characteristic impedance Zc which is calculated by the detection unit 14 when the measurement signal is outputted to the transmission line 10A having been subjected to the bending test BT1 and a subsequent bending test BT2.

With reference to FIG. 20, for example, when the frequency of the measurement signal is 20 MHz, the absolute value AZc 1 of the characteristic impedance Zc in the state where some of the strands 3 are broken is about 0.75 (2 smaller than the absolute value AZc_bef of the characteristic impedance Zc in the state where none of the strands 3 are broken. For example, when the frequency of the measurement signal is 20 MHz, the absolute value AZc 2 of the characteristic impedance Zc in the state where some of the strands 3 are broken is about 1.2Ω smaller than the absolute value AZc_bef of the characteristic impedance Zc in the state where none of the strands 3 are broken.

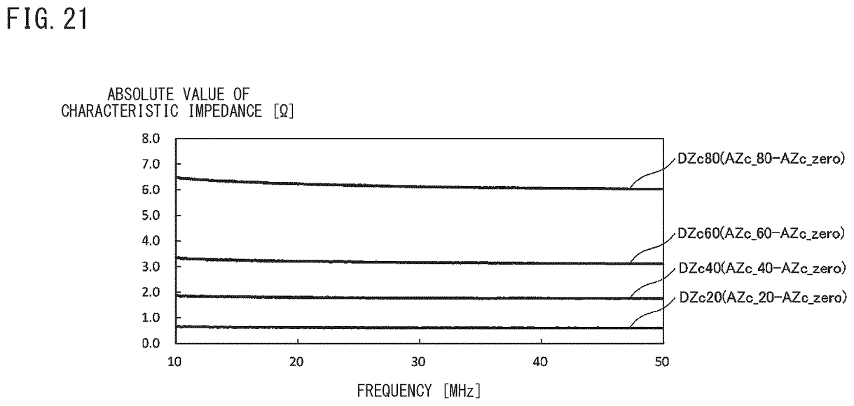

FIG. 21 shows a simulation result of an absolute value AZc of a characteristic impedance Zc calculated by the detection unit in the detection device according to the embodiment of the present disclosure. In FIG. 21, the horizontal axis indicates the frequency [MHz] of the measurement signal, and the vertical axis indicates the absolute value [Ω] of the characteristic impedance. FIG. 21 shows a difference DZc20 obtained by subtracting an absolute value AZc_zero from an absolute value AZc_20, a difference DZc40 obtained by subtracting the absolute value AZc_zero from an absolute value AZc_40, a difference DZc60 obtained by subtracting the absolute value AZc_zero from an absolute value AZc_60, and a difference DZc80 obtained by subtracting the absolute value AZc_zero from an absolute value AZc_80. Here, the absolute value AZc_zero is an absolute value AZc of a characteristic impedance Zc which is calculated by the detection unit 14 when a measurement signal is outputted to a transmission line 10B whose percentage of breakage is 0%. The absolute value AZc_20 is an absolute value AZc of a characteristic impedance Zc which is calculated by the detection unit 14 when the measurement signal is outputted to the transmission line 10B whose percentage of breakage is 20%. The absolute value AZc_40 is an absolute value AZc of a characteristic impedance Zc which is calculated by the detection unit 14 when the measurement signal is outputted to the transmission line 10B whose percentage of breakage is 40%. The absolute value AZc_60 is an absolute value AZc of a characteristic impedance Zc which is calculated by the detection unit 14 when the measurement signal is outputted to the transmission line 10B whose percentage of breakage is 60%. The absolute value AZc_80 is an absolute value AZc of a characteristic impedance Zc which is calculated by the detection unit 14 when the measurement signal is outputted to the transmission line 10B whose percentage of breakage is 80%.

With reference to FIG. 21, the differences DZc80, DZc60, DZc40, DZc20 are arranged in descending order, and are all positive values. That is, the absolute value AZc_80 of the characteristic impedance Zc calculated when the percentage of breakage is 80%, the absolute value AZc_60 of the characteristic impedance Zc calculated when the percentage of breakage is 60%, the absolute value AZc_40 of the characteristic impedance Zc calculated when the percentage of breakage is 40%, the absolute value AZc_20 of the characteristic impedance Zc calculated when the percentage of breakage is 20%, and the absolute value AZc_zero of the characteristic impedance Zc calculated when the percentage of breakage is 0%, are arranged in descending order.

According to the simulation result described with reference to FIG. 20 and FIG. 21, it is possible to determine, based on the characteristic impedance Zc, whether or not some of the plurality of strands 3 in the core wire 1 of the transmission line 10 are broken, the degree of progress of breakage of the strands 3 in the core wire 1, and the percentage of breakage of the transmission line 10.

For example, the storage unit 15 has, stored therein, a reference value SZc of the characteristic impedance Zc. The reference value SZc is set in advance based on an absolute value AZc of a characteristic impedance Zc which is calculated by the detection unit 14 when a measurement signal of a specific frequency is outputted to the target transmission line in which none of the strands 3 are broken. The reference value SZc may be set in advance based on a plurality of absolute values AZc which are calculated, when measurement signals of a plurality of specific frequencies are outputted to the target transmission line in which none of the strands 3 are broken, by the detection unit 14 for the respective frequencies of the measurement signals.

After calculating the absolute value AZc, the detection unit 14 acquires the reference value SZc from the storage unit 15, and calculates a difference DZc by subtracting the reference value SZc from the absolute value AZc.

For example, the detection unit 14 compares the calculated difference DZc with a predetermined threshold value ThZc, and determines, based on the comparison result, whether or not some of the plurality of strands 3 in the core wire 1 of the target transmission line are broken. More specifically, the detection unit 14 determines that none of the strands 3 in the core wire 1 are broken, when the difference DZc is equal to or larger than the threshold value ThZc, whereas the detection unit 14 determines that some of the plurality of strands 3 in the core wire 1 are broken, when the difference DZc is less than the threshold value ThZc.

For example, the threshold value ThZc is set in advance based on the above-described absolute values AZc_bef, AZc_1, and AZc_2.

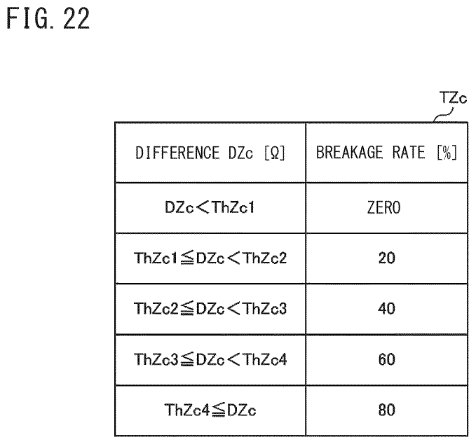

FIG. 22 shows an example of a determination table stored in the storage unit in the detection device according to the embodiment of the present disclosure. With reference to FIG. 22, the storage unit 15 has, stored therein, a determination table TZc indicating the correspondence between the difference DZc calculated by the detection unit 14 and the percentage of breakage.

For example, the detection unit 14 determines the percentage of breakage of the target transmission line, based on the calculated difference DZc, and the determination table TZc stored in the storage unit 15. More specifically, the detection unit 14 determines that the percentage of breakage is 0% when the difference DZc is less than a threshold value ThZc1. The detection unit 14 determines that the percentage of breakage is 20% when the difference DZc is equal to or larger than the threshold value ThZc1 and less than a threshold value ThZc2. The detection unit 14 determines that the percentage of breakage is 40% when the difference DZc is equal to or larger than the threshold value ThZc2 and less than a threshold value ThZc3. The detection unit 14 determines that the percentage of breakage is 60% when the difference DZc is equal to or larger than the threshold value ThZc3 and less than a threshold value ThZc4. The detection unit 14 determines that the percentage of breakage is 80% when the difference DZc is equal to or larger than the threshold value ThZc4.

For example, the threshold values ThZc1, ThZc2, ThZc3, ThZc4 are set in advance based on the above-described absolute values AZc_zero, AZc_20, AZc_40, AZc_60, AZc_80.

When the detection unit 14 has determined that the target transmission line is partially broken, the detection unit 14 notifies the user of the determination result via a communication unit (not shown) and the communication device 111. Specifically, the detection unit 14 notifies the user of the determination result indicating that some of the plurality of strands 3 in the core wire 1 are broken, and the determination result indicating the percentage of breakage of the target transmission line.

For example, the storage unit 15 has, stored therein, correspondence information indicating the correspondence between the target transmission line, and the type of the evaluation value EV to be used when the detection process is performed on the target transmission line. The detection unit 14 calculates the evaluation value EV of the type corresponding to the target transmission line, according to the correspondence information stored in the storage unit 15, and detects a partial damage of the target transmission line, based on the calculated evaluation value EV. That is, the detection unit 14 performs any one of detection examples 1 to 8 described above, according to the correspondence information stored in the storage unit 15, thereby detecting a partial damage of the target transmission line.

Alternatively, the detection unit 14 performs any two or more, or all of detection examples 1 to 8 to obtain a plurality of determination results, and detects a partial damage of the target transmission line by comprehensively considering the determination results. As an example, the detection unit 14 performs detection examples 1 to 8, and if the detection unit 14 determines, for at least one detection example, that some of the plurality of strands 3 in the core wire 1 are broken, the detection unit 14 notifies the user of the determination result indicating that some of the plurality of strands 3 in the core wire 1 are broken.

The detection unit 14 may calculate other evaluation values EV indicating electrical characteristics of the target transmission line, instead of the phase difference pd, the reflection coefficient rc, the impedance Z, the reactance X, the resistance R, the capacitance C, the inductance L, and the characteristic impedance Zc.

### [Operation Flow]

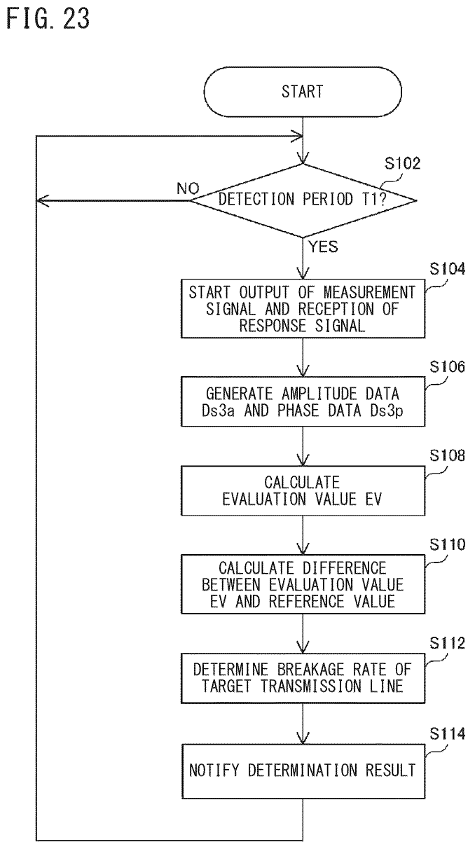

FIG. 23 is a flowchart showing an example of an operation procedure when the relay device according to the embodiment of the present disclosure performs a detection process.

With reference to FIG. 23, firstly, the relay device 101 waits for arrival of a detection period T1 (NO in step S102). When the detection period T1 has arrived (YES in step S102), the relay device 101 starts output of a measurement signal and reception of a response signal (step S104).

Next, the relay device 101 measures an amplitude and a phase of the received response signal. More specifically, the relay device 101 generates amplitude data Ds3a indicating an amplitude of a reflection signal included in the response signal, and phase data Ds3p indicating a phase of the reflection signal (step S106).

Next, the relay device 101 calculates an evaluation value EV, based on amplitude data Ds1a indicating the amplitude of the measurement signal, phase data Ds1p indicating the phase of the measurement signal, the amplitude data Ds3a, and the phase data Ds3p (step S108).

Next, the relay device 101 calculates a difference between the calculated evaluation value EV and the reference value of the evaluation value EV (step S110).

Next, the relay device 101 determines the percentage of breakage of the target transmission line, based on the calculated difference, and the determination table stored in the storage unit 15 (step S112).

Next, the relay device 101 notifies the user of the determination result indicating the percentage of breakage of the target transmission line, when the percentage of breakage of the target transmission line is 20% or more, for example (step S114).

Next, the relay device 101 waits for arrival of a new detection period T1 (NO in step S102).

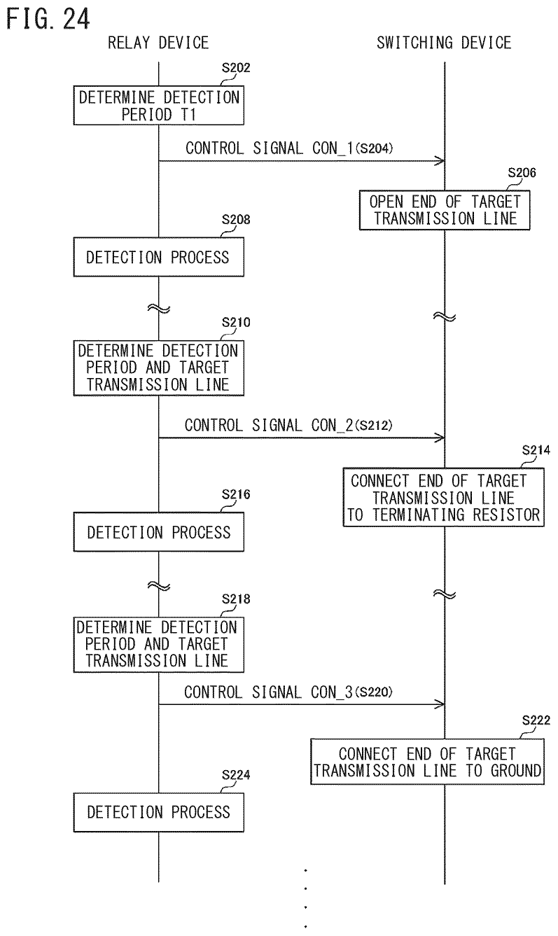

FIG. 24 shows an example of a sequence of a detection process in the detection system according to the embodiment of the present disclosure.

With reference to FIG. 24, firstly, the relay device 101 determines a detection period T1 (step S202).

Next, the relay device 101 transmits, to the switching device 151, a control signal CON_1 for switching the target transmission line to the open state, for example (step S204).

Next, the switching device 151 controls the switch 161 according to the control signal CON_1 received from the relay device 101 to switch the target transmission line to the open state (step S206).

Next, the relay device 101 performs a detection process. More specifically, with the target transmission line being in the open state, the relay device 101 starts output of a measurement signal and reception of a response signal, and calculates a phase difference pd as an example of an evaluation value EV, by using the phase data Ds3p indicating the phase of the reflection signal included in the response signal, and the phase data Ds1p indicating the phase of the measurement signal. Then, based on the calculated phase difference pd, the relay device 101 detects a partial damage of the target transmission line (step S208).

Next, the relay device 101 determines a detection period T1 (step S210).

Next, the relay device 101 transmits, to the switching device 151, a control signal CON_2 for switching the target transmission line to the matching state, for example (step S212).

Next, the switching device 151 controls the switch 161 according to the control signal CON_2 received from the relay device 101 to switch the target transmission line to the matching state (step S214).

Next, the relay device 101 performs a detection process. More specifically, with the target transmission line being in the matching state, the relay device 101 starts output of a measurement signal and reception of a response signal, and calculates a reflection coefficient re as an example of an evaluation value EV, by using the amplitude data Ds3a indicating the amplitude of the reflection signal included in the response signal, and the amplitude data Ds1a indicating the amplitude of the measurement signal. Then, based on the calculated reflection coefficient rc, the relay device 101 detects a partial damage of the target transmission line (step S216).

Next, the relay device 101 determines a detection period T1 (step S218).

Next, the relay device 101 transmits, to the switching device 151, a control signal CON_3 for switching the target transmission line to the short-circuit state, for example (step S220).

Next, the switching device 151 controls the switch 161 according to the control signal CON_3 received from the relay device 101 to switch the target transmission line to the short-circuit state (step S222).

Next, the relay device 101 performs a detection process. More specifically, with the target transmission line being in the short-circuit state, the relay device 101 starts output of a measurement signal and reception of a response signal, and calculates a reflection coefficient rc by using the amplitude data Ds3a indicating the amplitude of the reflection signal included in the response signal, and the amplitude data Ds1a indicating the amplitude of the measurement signal. The relay device 101 calculates an impedance Zst by using the reflection coefficient re, and acquires an inductance L as an example of an evaluation value EV from the impedance Zst. Then, based on the calculated inductance L, the relay device 101 detects a partial damage of the target transmission line (step S224).

The detection system 201 may not necessarily perform some or all of steps S204, S212, S220 in the sequence shown in FIG. 24. In this case, for example, the switching device 151 causes the connection state of the end of the target transmission line to change in a predetermined cycle.

More specifically, in the initial state, the switching device 151 switches the target transmission line to, for example, the open state, and waits for output of a measurement signal by the relay device 101. The relay device 101 starts the first detection process, i.e., outputs the measurement signal, with turn-on of the power source of the vehicle in which the communication system 301 is installed, as a trigger.

Next, upon detecting the measurement signal outputted to the target transmission line, the switching device 151 controls the switch 161 to switch the target transmission line to the matching state, at a timing when a predetermined time has elapsed from when the measurement signal was detected. Thereafter, the relay device 101 starts the second detection process, i.e., outputs the measurement signal, at a timing when a predetermined time has elapsed from when the first detection process was started.

Next, upon detecting the measurement signal outputted to the target transmission line, the switching device 151 controls the switch 161 to switch the target transmission line to the short-circuit state at a timing when a predetermined time has elapsed from when the measurement signal was detected. Thereafter, the relay device 101 starts the third detection process, i.e., outputs the measurement signal, at a timing when a predetermined time has elapsed from when the second detection process was started.

In the communication system 301 according to the embodiment of the present disclosure, the relay device 101 is connected to a communication device 111 on a one-to-one basis via a transmission line 10. However, the present disclosure is not limited thereto. The relay device 101 may be connected to a plurality of communication devices 111 on a one-to-many basis via a bus type transmission line 10.

In the communication system 301 according to the embodiment of the present disclosure, the relay device 101 performs the detection process. However, the present disclosure is not limited thereto. In the communication system 301, a device other than the relay device 101 may perform the detection process. Specifically, for example, a communication device 111 may function as a detection device to perform the detection process.

The detection system 201 according to the embodiment of the present disclosure includes the switching devices 151 and the switches 161. However, the present disclosure is not limited thereto. The detection system 201 may not necessarily include the switching devices 151 and the switches 161. In this case, the end, on the communication device 111 side, of the transmission line 10 is open, is connected to the ground node, or is connected to the ground node via a termination circuit 171, in a fixed manner.

In the detection system 201 according to the embodiment of the present disclosure, the relay device 101 performs the detection process when the end, on the communication device 111 side, of the target transmission line is in the test state. However, the present disclosure is not limited thereto. The relay device 101 may perform the detection process when the end, on the communication device 111 side, of the target transmission line is in the normal state. In this case, for example, the relay device 101 performs frequency division multiplexing of a communication signal and a measurement signal. More specifically, during the period in which the relay unit 11 performs the relay process, the signal output unit 12 generates a measurement signal having a frequency band different from the frequency band of the communication signal transmitted and received by the relay unit 11, and outputs the measurement signal to the target transmission line.

In the relay device 101 according to the embodiment of the present disclosure, the measurement unit 13 receives the response signal, which includes the measurement signal outputted from the signal output unit 12 and the reflection signal that is a signal in which the measurement signal is reflected, from the target transmission line via the corresponding communication port 16. However, the present disclosure is not limited thereto. The measurement unit 13 may receive the response signal that does not include the measurement signal. That is, the measurement unit 13 may receive the reflection signal as the response signal. More specifically, for example, the signal output unit 12 outputs the measurement signal to the target transmission line via a directional coupler and the communication port 16. The measurement unit 13 receives the response signal that does not include the measurement signal, from the target transmission line via the communication port 16 and the directional coupler.

In the relay device 101 according to the embodiment of the present disclosure, the measurement unit 13 generates the digital signal Ds3 indicating the reflection signal by subtracting the digital signal Ds1 from the digital signal Ds2. However, the present disclosure is not limited thereto. The measurement unit 13 may receive the measurement signal from the signal output unit 12, subtract the measurement signal from the received response signal to generate an analog signal indicating the reflection signal, and perform digital conversion on the generated analog signal to generate the digital signal Ds3.

In the relay device 101 according to the embodiment of the present disclosure, the detection unit 14 detects the degree of damage of the target transmission line. However, the present disclosure is not limited thereto. The detection unit 14 may not necessarily detect the degree of damage of the target transmission line while detecting a partial damage of the target transmission line.

In the relay device 101 according to the embodiment of the present disclosure, the detection unit 14 transmits the control signals CON_1, CON_2, CON_3 to the switching device 151 via the signal line (not shown). However, the present disclosure is not limited thereto. The detection unit 14 may transmit the control signals CON_1, CON_2, CON_3 to the switching device 151 via the cable part 5A in the target transmission line. More specifically, for example, the detection unit 14 transmits the control signals CON_1, CON_2, CON_3 to the switching device 151 via the cable part 5A before the signal output unit 12 outputs the measurement signal to the target transmission line.

For example, the detection unit 14 generates the control signals CON_1, CON_2, CON_3 having frequency bands different from the frequency band of the communication signal transmitted and received by the relay unit 11, multiplexes the generated control signals CON_1, CON_2, CON_3 with the communication signal, and outputs the resultant signal to the cable part 5A. As an example, the detection unit 14 multiplexes the control signals CON_1, CON_2, CON_3 being DC signals with the communication signal, and outputs the resultant signal to the cable part 5A. The switching device 151 separates the control signals CON_1, CON_2, CON_3 from the signal received via the cable part 5A to acquire the control signals CON_1, CON_2, CON_3.

Meanwhile, there is a demand for a technology capable of predicting a breakage of the transmission line 10, with a simple configuration. More specifically, a damage in the transmission line 10 gradually progresses due to aging, fatigue deterioration caused by bending, impact from the outside, etc., and finally, the transmission line 10 breaks. In order to take an appropriate countermeasure such as replacement of the transmission line 10 before the transmission line 10 breaks, a technology capable of predicting a breakage of the transmission line 10 is desired.

For example, a technology of detecting the characteristics of the transmission line 10 by using TDR (Time Domain Reflectometry) has been conventionally known. When an attempt is made to detect a change in the characteristics of the transmission line 10 by using such a technology and predict breakage of the transmission line 10 based on the detection result, it is necessary to output a rising pulse to the transmission line 10 with high reproducibility in order to accurately detect a change in the characteristics of the transmission line 10. As a result, a high performance pulse signal generator is required.

Meanwhile, when an attempt is made to measure the characteristics such as an S parameter of the transmission line 10 by using a network analyzer and predict breakage of the transmission line 10 based on the measurement result, expensive and complex measurement equipment is required in order to ensure sufficient detection accuracy, and furthermore, calibration of the measurement equipment is required for each measurement.

In contrast, in the relay device 101 according to the embodiment of the present disclosure, the signal output unit 12 outputs a measurement signal having a frequency component to the transmission line 10. The measurement unit 13 receives, from the transmission line 10, the response signal including the signal in which the measurement signal is reflected, and measures at least one of the amplitude and the phase of the received response signal. The detection unit 14 calculates the evaluation value EV based on the measurement result of the measurement unit 13, and detects a partial damage of the transmission line 10, based on the calculated evaluation value EV.

As described above, a measurement signal having a frequency component is outputted to a transmission line 10, an evaluation value EV is calculated based on a measurement result of at least one of an amplitude and a phase of a response signal received from the transmission line 10, and a partial damage of the transmission line 10 is detected based on the calculated evaluation value EV. Therefore, a partial damage of the transmission line 10 can be detected without requiring a breakage detecting line other than the transmission line 10. Consequently, breakage of the transmission line 10 can be predicted with a simple configuration.

The above embodiment is merely illustrative in all aspects and should not be recognized as being restrictive. The scope of the present disclosure is defined by the scope of the claims rather than by the description above, and is intended to include meaning equivalent to the scope of the claims and all modifications within the scope.

The processes (functions) of the above-described embodiment may be realized by processing circuitry including one or more processors. In addition to the one or more processors, the processing circuitry may include an integrated circuit or the like in which one or more memories, various analog circuits, and various digital circuits are combined. The one or more memories have, stored therein, programs (instructions) that cause the one or more processors to execute the processes. The one or more processors may execute the processes according to the program read out from the one or more memories, or may execute the processes according to a logic circuit designed in advance to execute the processes. The above processors may include a CPU (Central Processing Unit), a GPU (Graphics Processing Unit), a DSP (Digital Signal Processor), an FPGA (Field Programmable Gate Array), an ASIC (Application Specific Integrated Circuit), etc., which are compatible with computer control. The physically separated processors may execute the processes in cooperation with each other. For example, the processors installed in physically separated computers may execute the processes in cooperation with each other through a network such as a LAN (Local Area Network), a WAN (Wide Area Network), or the Internet. The program may be installed in the memory from an external server device or the like through the network. Alternatively, the program may be distributed in a state of being stored in a recording medium such as a CD-ROM (Compact Disc Read Only Memory), a DVD-ROM (Digital Versatile Disk Read Only Memory), or a semiconductor memory, and may be installed in the memory from the recording medium.

The above description includes the features in the additional notes below.

### [Additional Note 1]

A detection device comprising:
a signal output unit configured to output a measurement signal having a frequency component to a transmission line;
a measurement unit configured to receive, from the transmission line, a response signal including a signal in which the measurement signal is reflected, and measure at least one of an amplitude and a phase of the received response signal; and
a detection unit configured to calculate an evaluation value based on a measurement result obtained by the measurement unit, and detect a partial damage of the transmission line, based on the calculated evaluation value, wherein
the detection unit transmits a control signal to a switching device provided outside the detection device, the control signal being for switching the state of an end, different from an input end for the measurement signal, of the transmission line, between an open state, a short-circuit state, and a load-connected state.

### [Additional Note 2]

A detection device comprising processing circuitry,
the processing circuitry being configured to:
output a measurement signal having a frequency component to a transmission line;
receive, from the transmission line, a response signal including a signal in which the measurement signal is reflected, and measure at least one of an amplitude and a phase of the received response signal; and
calculate an evaluation value based on a measurement result of at least one of the amplitude and the phase, and detect a partial damage of the transmission line, based on the calculated evaluation value.

### REFERENCE SIGNS LIST

1 core wire
2 sheath
3, 3A, 3B strand
4 insulating layer
5A cable part
5B, 5C connector part
10, 10A, 10B transmission line
11 relay unit
12 signal output unit
13 measurement unit
14 detection unit
15 storage unit
16 communication port
21 detection processing unit
101 relay device
111 communication device
151 switching device
161 switch
171 termination circuit
201 detection system
301 communication system
Tpd, Tre, TC, TL, TZc determination table

1. A detection device comprising:
a signal output unit configured to output a measurement signal having a frequency component to a transmission line;
a measurement unit configured to receive, from the transmission line, a response signal including a signal in which the measurement signal is reflected, and measure at least one of an amplitude and a phase of the received response signal; and
a detection unit configured to calculate an evaluation value based on a measurement result obtained by the measurement unit, and detect a partial damage of the transmission line, based on the calculated evaluation value.

2. The detection device according to claim 1, wherein
the transmission line includes a plurality of strands, and
the detection unit detects, as the partial damage of the transmission line, breakage of some of the plurality of strands.

3. The detection device according to claim 2, wherein
the transmission line includes a core wire in which the plurality of strands are bundled, and
the plurality of strands are insulated from each other in a partial area of the core wire.

4. The detection device according to claim 1, wherein the detection unit further detects a degree of damage of the transmission line that is partially damaged.

5. The detection device according to claim 1, wherein
the detection unit calculates, as the evaluation value, at least one of: a phase difference between the measurement signal and the response signal; a reflection coefficient that is a ratio of an amplitude of the response signal to an amplitude of the measurement signal; an impedance of the transmission line; a reactance of the transmission line; a resistance of the transmission line; a capacitance of the transmission line; an inductance of the transmission line; and a characteristic impedance of the transmission line.

6. A detection system comprising:
a detection device; and
a switching device,
the detection device performing a detection process that includes outputting a measurement signal having a frequency component to a transmission line, receiving, from the transmission line, a response signal including a signal in which the measurement signal is reflected, measuring at least one of an amplitude and a phase of the received response signal, calculating an evaluation value based on a measurement result, and detecting a partial damage of the transmission line, based on the calculated evaluation value,
the switching device performing a process of switching a state of an end, different from an input end for the measurement signal, of the transmission line, between a normal state where the detection device is allowed to communicate with another device via the transmission line, and a test state where the detection device is allowed to perform the detection process, wherein
the process of switching the state of the end to the test state is at least one of a process of switching to a state where the end is open, a process of switching to a state where the end is connected to a ground node, and a process of switching to a state where the end is connected to a load for a test,
the detection device transmits a control signal to the switching device via the transmission line, and
the switching device performs the process of switching the state of the end to the test state, according to the control signal received from the detection device.

7. A transmission line comprising:
a cable part; and
a connector part provided at a first end of the cable part,
the connector part including a switching device configured to perform a process of switching a state of the first end between a normal state where communication via the transmission line is allowed, and a test state where a test of the transmission line is allowed, wherein
the process of switching the state of the first end to the test state is at least one of a process of switching to a state where the first end is open, a process of switching to a state where the first end is connected to a ground node, and a process of switching to a state where the first end is connected to a load for the test.

8. A detection method in a detection device, comprising:
outputting a measurement signal having a frequency component to a transmission line;
receiving, from the transmission line, a response signal including a signal in which the measurement signal is reflected, and measuring at least one of an amplitude and a phase of the received response signal; and
performing a detection process of calculating an evaluation value based on a measurement result, and detecting a partial damage of the transmission line, based on the calculated evaluation value, wherein
the performing the detection process includes performing a process of switching a state of an end, different from an input end for the measurement signal, of the transmission line, between a normal state where the detection device is allowed to communicate with another device via the transmission line, and a test state where the detection device is allowed to perform the detection process,
the process of switching the state of the end to the test state is at least one of a process of switching to a state where the end is open, a process of switching to a state where the end is connected to a ground node, and a process of switching to a state where the end is connected to a load for a test, and
the performing the detection process includes transmitting a control signal for switching the state of the end via the transmission line, as the process of switching the state of the end to the test state.

9. A detection device comprising:
a signal output unit configured to output a measurement signal having a frequency component to a transmission line;
a measurement unit configured to receive, from the transmission line, a response signal including a signal in which the measurement signal is reflected, and measure at least one of an amplitude and a phase of the received response signal; and
a detection unit configured to perform a detection process of calculating an evaluation value based on a measurement result obtained by the measurement unit, and detecting a partial damage of the transmission line, based on the calculated evaluation value, wherein
the detection unit performs a process of switching a state of an end, different from an input end for the measurement signal, of the transmission line, between a normal state where the detection device is allowed to communicate with another device via the transmission line, and a test state where the detection device is allowed to perform the detection process,
the process of switching the state of the end to the test state is at least one of a process of switching to a state where the end is open, a process of switching to a state where the end is connected to a ground node, and a process of switching to a state where the end is connected to a load for a test, and
the detection unit transmits a control signal for switching the state of the end via the transmission line, as the process of switching the state of the end to the test state.

10. The detection device according to claim 9, wherein
the transmission line includes a switching device configured to perform the process of switching the state of the end, and
the detection unit transmits the control signal to the switching device.
